(19) United States
(12) Patent Application Publication
(10) Pub. No.: US 2026/0136816 A1
(43) Pub. Date: May 14, 2026

(54) Display Apparatus

(71) Applicant: LG Display Co., Ltd., Seoul (KR)

(72) Inventors: Heesu Byeon, Paju-si (KR); Pureum Kim, Paju-si (KR)

(21) Appl. No.: 19/179,515

(22) Filed: Apr. 15, 2025

(30) Foreign Application Priority Data
May 20, 2024 (KR) 10-2024-0064993

(51) Int. Cl. H10K 59/80; H10K 59/122

(52) U.S. Cl. CPC H10K 59/8791; H10K 59/122

(57) ABSTRACT

A display apparatus may include a substrate including sub-pixels, an insulating layer disposed on the substrate and having a trench formed between the adjacent sub-pixels, and a filling member disposed in the trench, wherein the trench includes a first trench extending in a first direction and disposed between the adjacent sub-pixels in a second direction intersecting the first direction, a second trench extending in the second direction and disposed between the adjacent sub-pixels in the first direction, and an intersection trench located in an intersection area between the first trench and the second trench, and the filling member is located in the intersection trench.

### CROSS REFERENCE TO RELATED APPLICATION

The present application claims priority to Republic of Korea Patent Application No. 10-2024-0064993, filed May 20, 2024, which is hereby incorporated by reference in its entirety.

### BACKGROUND

### Field of Technology

The present specification relates to a display apparatus.

### Description of the Related Art

As the information society develops, various demands for display apparatuses for displaying images are increasing, and various types of display apparatuses, such as a liquid crystal display (LCD) apparatus and an organic light-emitting diode (OLED) display apparatus, are being utilized.

Among the display apparatuses, there is an advantage in that the OLED display apparatus as the self-luminous type has a wider viewing angle, a higher contrast ratio, is lighter and thinner, and has less power consumption than the LCD apparatus. In addition, there is an advantage in that the OLED display apparatus can drive at a low voltage, have a fast response time, and especially have the inexpensive manufacturing cost.

Recently, demand for a display apparatus that requires augmented reality (AR), virtual reality (VR), or equivalent ultra-high resolution using such an OLED display apparatus is increasing.

### SUMMARY

The present specification is directed to providing a display apparatus in which it is possible to more easily prevent or at least reduce a leakage current from occurring between sub-pixels by forming a trench in a boundary of the sub-pixel.

The present specification is also directed to providing a display apparatus in which it is possible to prevent or at least reduce light color mixing by forming a trench in a boundary of a sub-pixel.

The present specification is also directed to providing a display apparatus in which it is possible to prevent a short circuit between a charge generation layer and a cathode electrode in an area in which a trench is formed.

Objects of the present specification are not limited to the above-described objects, and other technical objects may be inferred from the following embodiments.

According to one embodiment of the present specification, there is provided a display apparatus including a substrate including sub-pixels, an insulating layer disposed on the substrate and having a trench formed between the adjacent sub-pixels, and a filling member disposed in the trench, wherein the trench includes a first trench extending in a first direction and disposed between the adjacent sub-pixels in a second direction intersecting the first direction, a second trench extending in the second direction and disposed between the adjacent sub-pixels in the first direction, and an intersection trench located in an intersection area between the first trench and the second trench, and the filling member is located in the intersection trench.

According to one embodiment of the present specification, there is provided a display apparatus including a substrate including sub-pixels, an insulating layer disposed on the substrate and having a trench formed between the adjacent sub-pixels, and a filling member disposed in the trench, wherein the filling member is spaced apart from the insulating layer, and a thickness of the filling member is smaller than a thickness of the insulating layer.

Detailed matters of other embodiments are included in the detailed description and accompanying drawings.

According to the embodiments of the present specification, it is possible to more easily prevent a leakage current from occurring between the sub-pixels by forming the trench in the boundary of the sub-pixel.

According to the embodiments of the present specification, it is possible to prevent or at least reduce light color mixing by forming the trench in the boundary of the sub-pixel.

According to the embodiments of the present specification, it is possible to prevent or at least reduce a short circuit between the charge generation layer and the cathode electrode in the area in which the trench is formed.

According to the embodiments of the present specification, it is possible to prevent or at least reduce a leakage current between the sub-pixels and a short circuit defect between the charge generation layer and the cathode electrode, thereby preventing or at least reducing light color mixing and more easily enabling color reproduction of the display apparatus.

However, effects obtainable from the present specification are not limited to the above-described effects, and other effects that are not mentioned will be able to be clearly understood by those skilled in the art to which the present specification pertains from the following description.

### BRIEF DESCRIPTION OF THE DRAWINGS

FIG. 1 is a plan view of a display apparatus according to one embodiment.

FIG. 2 is a cross-sectional view along line A-A′ in FIG. 1 according to one embodiment.

FIG. 3 is a cross-sectional view along line B-B′ in FIG. 1 according to one embodiment.

FIG. 4 is a cross-sectional view along line C-C′ in FIG. 1 according to one embodiment.

FIG. 5 is a cross-sectional view along line D-D′ in FIG. 1 according to one embodiment.

FIG. 6 is a cross-sectional view of an organic light-emitting diode (OLED) according to FIG. 2 according to one embodiment.

FIG. 7 is a cross-sectional view of an OLED according to a modified example of FIG. 2 according to one embodiment.

FIG. 8 is an enlarged view of area Q1 in FIG. 2 according to one embodiment.

FIG. 9 is an enlarged view of area Q2 in FIG. 5 according to one embodiment.

FIGS. 10 to 18 are cross-sectional views for each process in a method of manufacturing a display apparatus according to one embodiment.

FIGS. 19 to 28 are cross-sectional views for each process in a method of manufacturing a display apparatus according to another embodiment.

FIG. 29 is a cross-sectional view of an intersection trench area of the display apparatus according to another embodiment.

FIG. 30 is an enlarged view of area Q3 in FIG. 29 according to one embodiment.

FIGS. 31 to 39 are cross-sectional views for each process in a method of manufacturing a display apparatus according to the embodiment of FIGS. 29 and 30.

FIG. 40 is a cross-sectional view of a display apparatus according to another embodiment.

FIG. 41 is a cross-sectional view of a display apparatus according to still another embodiment.

### DETAILED DESCRIPTION

Hereinafter, embodiments will be described with reference to the accompanying drawings. In the specification, when a first component (or an area, a layer, a portion, etc.) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

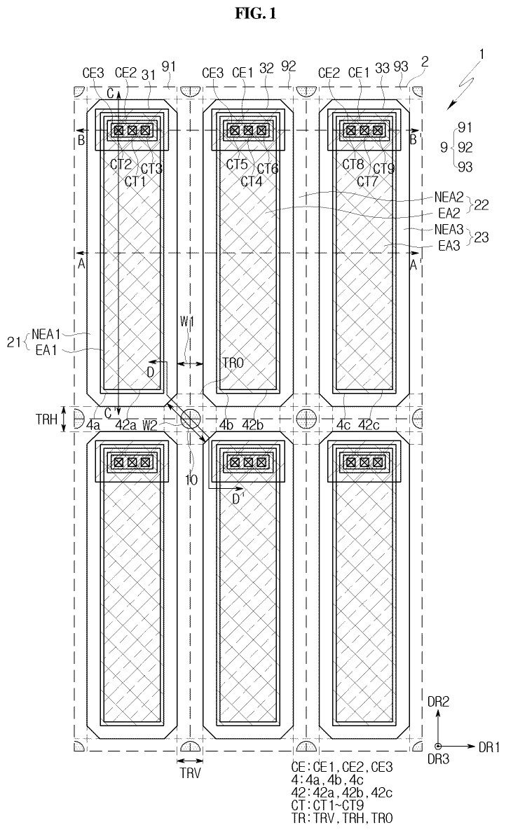

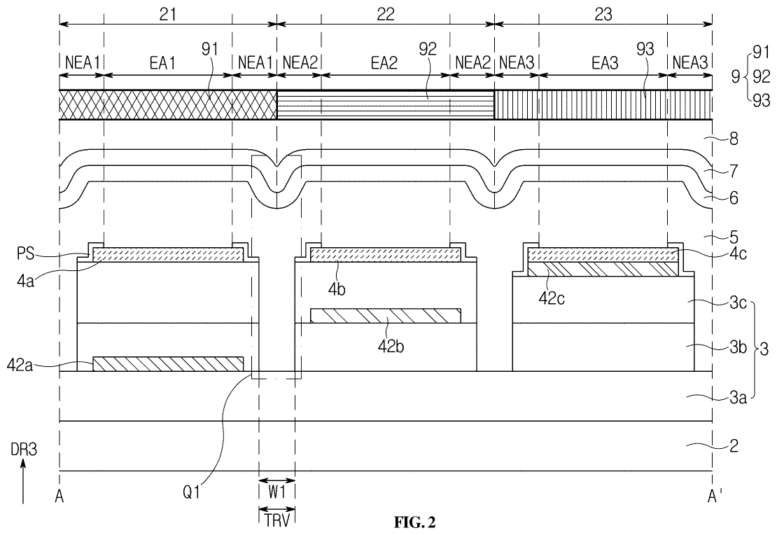

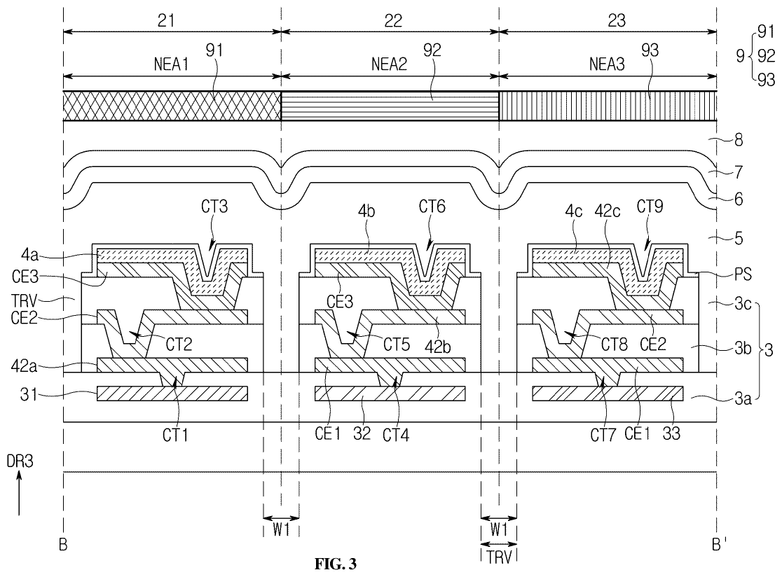

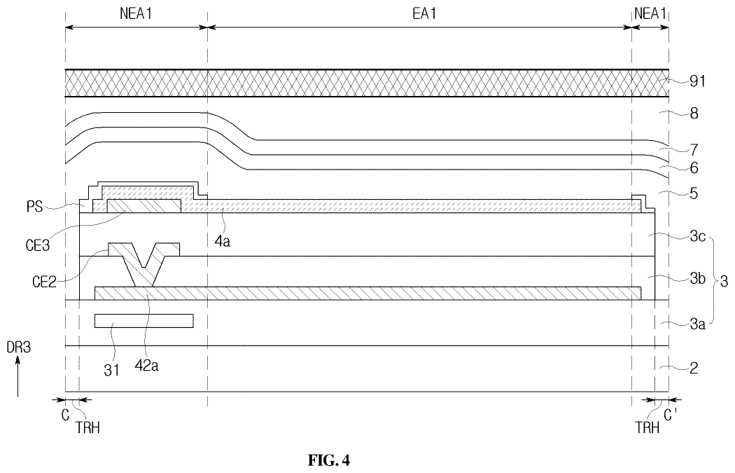

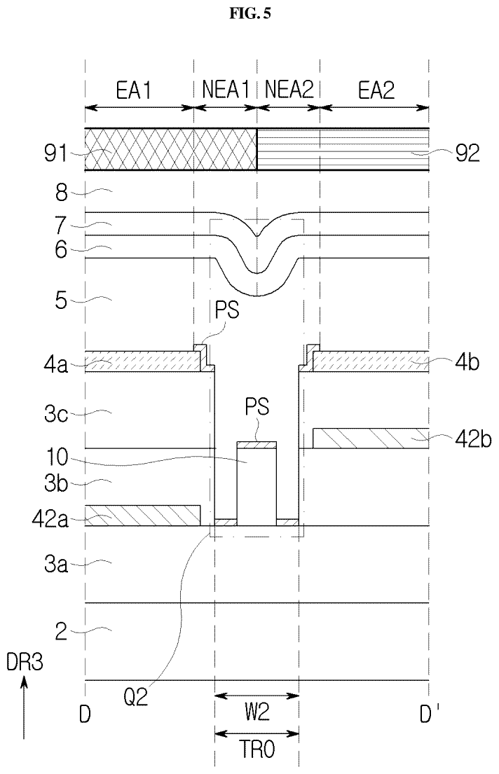

FIG. 1 is a plan view of a display apparatus according to one embodiment. FIG. 2 is a cross-sectional view along line A-A′ in FIG. 1 according to one embodiment. FIG. 3 is a cross-sectional view along line B-B′ in FIG. 1 according to one embodiment. FIG. 4 is a cross-sectional view along line C-C′ in FIG. 1. FIG. 5 is a cross-sectional view along line D-D′ in FIG. 1 according to one embodiment.

Referring to FIGS. 1 to 5, a display apparatus 1 according to one embodiment includes a substrate 2, anode electrode layer 4 (4a, 4b, and 4c), a common light-emitting layer 5, and a cathode electrode 6.

A plurality of sub-pixels 21, 22, and 23 are formed on the substrate 2. The plurality of sub-pixels 21, 22, and 23 may form one pixel. The plurality of pixels may be formed on the substrate 2.

The plurality of sub-pixels 21, 22, and 23 include a first sub-pixel 21, a second sub-pixel 22, and a third sub-pixel 23. Since the first sub-pixel 21, the second sub-pixel 22, and the third sub-pixel 23 may be arranged sequentially, the first sub-pixel 21 may be disposed adjacent to one side, for example, the left side of the second sub-pixel 22, and the third sub-pixel 23 may be disposed adjacent to one side, for example, the right side of the second sub-pixel 22.

Throughout the present specification, when two sub-pixels are disposed adjacent to each other, it should be construed to mean that no other sub-pixels are disposed between the two sub-pixels.

The first sub-pixel 21 may be provided to emit red (R) light, the second sub-pixel 22 may be provided to emit green (G) light, and the third sub-pixel 23 may be provided to emit blue (B) light, but the embodiments of the present specification are not necessarily limited thereto.

FIG. 1 illustrates an example in which a pixel includes only three sub-pixels 21, 22, and 23, but the present specification is not limited thereto, and the pixel may include four sub-pixels. When the pixel includes four sub-pixels, the pixel may further include a fourth sub-pixel provided to emit white (W) light.

Each of the first to third sub-pixels 21, 22, and 23 may be provided to have the same size. For example, each of the first to third sub-pixels 21, 22, and 23 may be provided to have the same width and the same height.

Here, the width may refer to a horizontal direction (a first direction DR1) based on FIG. 1, and the height may refer to a direction (a second direction DR2) perpendicular to the width based on FIG. 1, but the present specification is not necessarily limited thereto. The first direction DR1 may intersect the second direction DR2, and a third direction DR3 may intersect the first direction DR1 and the second direction DR2. The third direction DR3 may refer to a thickness direction of the display apparatus 1, but is not limited thereto.

The first direction DR1, the second direction DR2, and the third direction DR3 should be understood as relative directions and are not limited to embodiments of the present specification.

A protective layer PS (or a bank) may be disposed on each of the first sub-pixel 21, the second sub-pixel 22, and the third sub-pixel 23. The protective layer PS may serve as a bank that defines light-emitting areas EA1, EA2, and EA3 of the sub-pixels 21, 22, and 23.

The protective layer PS is illustrated as being formed of a single layer, but is not limited thereto, and the protective layer PS may be formed of multiple layers.

Each sub-pixel 21, 22, or 23 may include the light-emitting area EA1, EA2, or EA3 and a non-light-emitting area NEA1, NEA2, or NEA3. The first sub-pixel 21 may include a first light-emitting area EA1 and a first non-light-emitting area NEA1 around the first light-emitting area EA1, the second sub-pixel 22 may include a second light-emitting area EA2 and a second non-light-emitting area NEA2 around the second light-emitting area EA2, and the third sub-pixel 23 may include a third light-emitting area EA3 and a third non-light-emitting area NEA3 around the third light-emitting area EA3. Each light-emitting area EA1, EA2, or EA3 may be the same as an area exposed from the protective layer PS of the anode electrode layer 4a, 4b, or 4c to be described below.

The anode electrode layer 4 is patterned for each individual sub-pixel 21, 22, or 23. That is, one anode electrode layer 4 is formed in the first sub-pixel 21, another anode electrode layer 4 is formed in the second sub-pixel 22, and still another anode electrode layer 4 is formed in the third sub-pixel 23.

The anode electrode layer 4 may include a first anode electrode 4a, a second anode electrode 4b, and a third anode electrode 4c. Each of the first anode electrode 4a, the second anode electrode 4b, and the third anode electrode 4c may be disposed in each sub-pixel 21, 22, or 23.

The anode electrode layer 4 may serve as an anode of the display apparatus 1. The protective layer PS may be provided to cover an edge of the anode electrode layer 4 disposed in each of the first to third sub-pixels 21, 22, and 23 to distinguish the first sub-pixel 21, the second sub-pixel 22, and the third sub-pixel 23.

The display apparatus 1 may have reflective electrodes 42 with different surface heights, thereby further increasing light extraction efficiency using the micro-cavity characteristic.

The micro-cavity characteristic refers to a characteristic that, when a distance between the reflective electrode 42 and the cathode electrode 6 is an integer multiple of a half wavelength (λ/2) of light emitted from a sub-pixel, constructive interference occurs to amplify the light, and when a reflection and re-reflection process is repeated between the reflective electrode 42 and the cathode electrode 6, a degree of amplication of light continuously increases, thereby increasing the external extraction efficiency of light.

The common light-emitting layer 5 may be provided to emit white light. For example, the common light-emitting layer 5 may be provided to emit white light by having a two-stack structure including a blue light-emitting layer, a yellow-green light-emitting layer, and a charge generation layer or a three-stack structure including a blue light-emitting layer, a green light-emitting layer, a red light-emitting layer, and a charge generation layer, but is not necessarily limited thereto, and may be formed of multiple layers exceeding 3 stacks as long as it may emit white light.

The common light-emitting layer 5 may be formed as a common layer across the first to third sub-pixels 21, 22, and 23.

The cathode electrode 6 is used to form an electric field with the anode electrode layer 4 and may serve as a cathode. The cathode electrode 6 may be disposed on an upper surface of the common light-emitting layer 5, which is opposite to a lower surface of the common light-emitting layer 5 that comes into contact with the anode electrode layer 4, and may be provided as a common layer across the first to third sub-pixels 21, 22, and 23.

In the case of a top emission type, the cathode electrode 6 may be provided as a first electrode, and in the case of a bottom emission type, the cathode electrode 6 may be provided as an opaque cathode electrode including a reflective material. In the case of the top emission type, the cathode electrode 6 may be formed as a cathode electrode including a translucent material to increase light extraction efficiency using the micro-cavity characteristic. Since the display apparatus 1 increases light extraction efficiency using the micro-cavity characteristic in the top emission type, an example in which the cathode electrode 6 is formed as a cathode electrode including a translucent material will be described.

A color filter layer 9 is provided in each of the first to third sub-pixels 21, 22, and 23 to block a specific color of light from light emitted from the light-emitting layer of each sub-pixel. The color filter layer 9 may include a first color filter 91 provided in the first sub-pixel 21, a second color filter 92 provided in the second sub-pixel 22, and a third color filter 93 provided in the third sub-pixel 23.

The first color filter 91 may be provided to block light of other colors excluding red (R) light. In this case, the first color filter 91 may be provided as a red color filter. The second color filter 92 may be provided to block light of other colors excluding green (G) light. In this case, the second color filter 92 may be provided as a green color filter. The third color filter 93 may be provided to block light of other colors excluding blue (B) light. In this case, the third color filter 93 may be provided as a blue color filter. However, the present specification is not necessarily limited thereto.

The first to third color filters 91, 92, and 93 provided in the first to third sub-pixels 21, 22, and 23, respectively, may be provided in the same size as the respective sub-pixels or provided by being reduced or expanded at a predetermined ratio to each sub-pixel.

Transistors 31, 32, and 33 may be disposed in the non-light-emitting areas NEA1, NEA2, and NEA3 of the sub-pixels 21, 22, and 23, respectively. For example, the transistors 31, 32, and 33 may be located at one sides of reflective electrodes 42a, 42b, and 42c in the second direction DR2, but are not limited thereto.

The transistors 31, 32, and 33 may be disposed in the light-emitting areas EA1, EA2, and EA3 and disposed under the reflective electrodes 42a, 42b, and 42c, and in this case, the transistors 31, 32, and 33 cannot be visible from the outside.

The anode electrode layers 4a, 4b, and 4c may be electrically connected to the corresponding transistors 31, 32, and 33 through connection electrodes CE (CE1, CE2, and CE3), the reflective electrodes 42a, 42b, and 42c, and contact holes CT (CT1 to CT9) that are disposed in the sub-pixels 21, 22, and 23, respectively.

A trench TR may be disposed between the sub-pixels 21, 22, and 23 (or between the light-emitting areas EA1, EA2, and EA3 of the sub-pixels 21, 22, and 23. The trench TR may be defined by a second insulating layer 3b and a third insulating layer 3c. The trench TR may be formed in a groove or recess shape in which the second insulating layer 3b and the third insulating layer 3c are removed to expose a first insulating layer 3a. The trench TR may be recessed from an upper surface of the insulating layer. The trench TR may recess the second insulating layer 3b and the third insulating layer 3c. The trench TR may be defined by a side surface of the second insulating layer 3b, a side surface of the third insulating layer 3c, and an upper surface of the first insulating layer 3a, but is not limited thereto.

The trench TR may include a first trench TRH, a second trench TRV, and an intersection trench TRO. The first trench TRH may extend in the first direction DR1 between the sub-pixels 21, 22, and 23 or between the adjacent sub-pixels in a second direction DR2 intersecting the first direction DR1, and the second trench TRV may extend in the second direction DR2 between the sub-pixels 21, 22, and 23 or between the adjacent sub-pixels in the first direction DR1. The intersection trench TRO may be disposed in an area in which the first trench TRH intersects the second trench TRV.

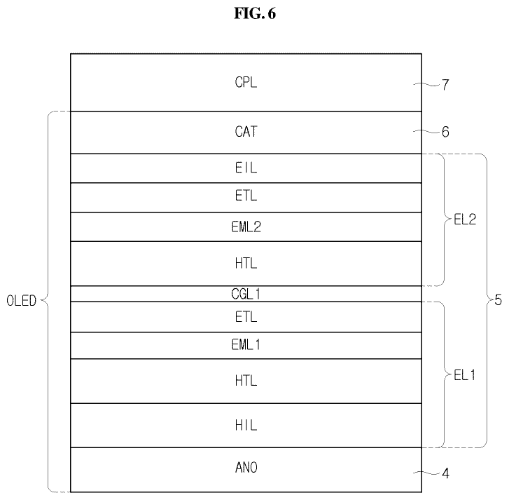

As the trench TR is disposed between the sub-pixels 21, 22, and 23, even when the common light-emitting layer 5 and the cathode electrode 6 are disposed on the sub-pixels 21, 22, and 23, a first stack EL1 (see FIG. 6) and a first charge generation layer CGL1 (see FIG. 6) are separated in each sub-pixel 21, 22, or 23, and a second stack EL2 (see FIG. 6) may be disposed between the first charge generation layer CGL1 (see FIG. 6) and the cathode electrode 6.

It is possible to prevent or at least reduce a leakage current between sub-pixels 21, 22, and 23, prevent a short circuit between the charge generation layer CGL1 and the cathode electrode 6, and prevent light color mixing.

The first trench TRH and the second trench TRV may extend in an extension direction and have a constant first width W1. The first trench TRH extending in the first direction DR1 may have the first width W1 in the second direction DR2, and the second trench TRV extending in the second direction DR2 may have the first width W1 in the first direction DR1.

The first trench TRH and the second trench TRV are described as having the same first width W1, but are not limited thereto, and the first trench TRH and the second trench TRV may have different widths.

The intersection trench TRO may have a second width W2 greater than the first width W1. In the intersection trench TRO in which the first trench TRH meets the second trench TRV, an etchant may be concentrated, and thus an edge thereof may be over-etched, and the intersection trench TRO may be formed to have the second width W2 greater than the first width W1.

A filling member 10 may be disposed in the intersection trench TRO. The filling member 10 may be provided as a plurality of filling members and disposed in each intersection trench TRO.

The filling member 10 is illustrated as having a circular shape in a plan view, but the shape of the filling member 10 in a plan view is not limited thereto. For example, the shape of the filling member 10 in a plan view may be formed as a polygon, such as a triangle, a quadrangle, a pentagon, etc., or a shape including a curve, such as an oval.

An upper surface (or a surface) of the filling member 10 may be disposed under an upper surface (or a surface) of the insulating layer 3. Here, the upper surface (or the surface) of the insulating layer 3 may refer to an upper surface (or a surface) of the third insulating layer 3c located at an uppermost layer among layers forming the insulating layer 3.

A thickness of the filling member 10 may be smaller than a thickness of the insulating layer 3. Here, each of the thickness of the filling member 10 and the thickness of the insulating layer 3 may refer to a thickness in the thickness direction (the third direction DR3) of the display apparatus 1.

The filling member 10 may include the same material as at least one of the second insulating layer 3b, the third insulating layer 3c, and the protective layer PS and may be formed by the same process, but is not limited thereto.

For example, when the filling member 10 includes the same material as the second insulating layer 3b, the filling member 10 may be formed by the same process as the second insulating layer 3b, and the thickness of the filling member 10 may be the same as the thickness of the second insulating layer 3b. The thickness of the filling member 10 and the thickness of the second insulating layer 3b may refer to the respective thicknesses in the thickness direction (the third direction DR3) of the display apparatus 1.

As another example, when the filling member 10 includes the same material as the third insulating layer 3c, the filling member 10 may be formed by the same process as the third insulating layer 3c, and the thickness of the filling member 10 may be the same as the thickness of the third insulating layer 3c. The thickness of the filling member 10 and the thickness of the third insulating layer 3c may refer to the respective thicknesses in the thickness direction (the third direction DR3) of the display apparatus 1.

The filling member 10 may be disposed to be spaced apart from the second insulating layer 3b and the third insulating layer 3c that define the intersection trench TRO. The filling member 10 may be disposed in the area of the intersection trench TRO and disposed to be spaced apart from the side surface of the second insulating layer 3b and the side surface of the third insulating layer 3c that are exposed by the intersection trench TRO.

As the filling member 10 is disposed in each intersection trench TRO, even when the intersection trench TRO has the second width W2 greater than the first width W1, the filling member 10 fills a part of the intersection trench TRO, and thus the first stack EL1 (see FIG. 6) and the first charge generation layer CGL1 (see FIG. 6) may be separated in each sub-pixel 21, 22, or 23, and the second stack EL2 (see FIG. 6) may be disposed between the first charge generation layer CGL1 (see FIG. 6) and the cathode electrode 6.

It is possible to prevent or at least reduce a leakage current between sub-pixels 21, 22, and 23, prevent or at least reduce a short circuit between the charge generation layer CGL1 and the cathode electrode 6, and prevent or at least reduce light color mixing. Detailed description thereof will be given below.

Hereinafter, the stacking structure of the display apparatus 1 according to one embodiment will be described in detail.

The display apparatus 1 according to one embodiment includes the substrate 2, the insulating layer 3, the anode electrode layer 4, the protective layer PS, the common light-emitting layer 5, the cathode electrode 6, a capping layer 7, an encapsulation layer 8, and the color filter layer 9.

The substrate 2 may be a plastic film, a glass substrate, or a semiconductor substrate, such as silicon.

The substrate 2 may be formed of a transparent material or an opaque material. The first sub-pixel 21, the second sub-pixel 22, and the third sub-pixel 23 are provided on the substrate 2. As another example, the first sub-pixel 21 may be provided to emit red (R) light, the second sub-pixel 22 may be provided to emit blue (B) light, and the third sub-pixel 23 may be provided to emit green (G) light.

Since the display apparatus 1 according to one embodiment is configured in a so-called top emission type in which emitted light is emitted upward, both a transparent material and an opaque material may be used as a material of the substrate 2. The color filters 91, 92, and 93 may be respectively provided above the first to third sub-pixels 21, 22, and 23 from which light is emitted to transmit light of the above colors.

The insulating layer 3 is formed on the substrate 2. The insulating layer 3 may include a plurality of insulating layers 3a, 3b, and 3c. Hereinafter, the insulating layer 3 is described as including the first to third insulating layers 3a, 3b, and 3c, but is not limited thereto, and an additional insulating layer may be further disposed between the first to third insulating layers 3a, 3b, and 3c.

The first insulating layer 3a is disposed on the substrate 2, and circuit elements including the plurality of thin film transistors 31, 32, and 33, various signal lines, capacitors, etc. are provided in the first insulating layer 3 a of each sub-pixel 21, 22, or 23. The signal lines may include a gate line, a data line, a power line, and a reference line, and the thin film transistors 31, 32, and 33 may include a switching thin film transistor, a driving thin film transistor, and a sensing thin film transistor. Each of the sub-pixels 21, 22, and 23 is defined by an intersection structure of gate lines and data lines.

The switching thin film transistor serves to supply the driving thin film transistor with a data voltage switched according to a gate signal supplied to the gate line and supplied from the data line.

The driving thin film transistor is switched according to the data voltage supplied from the switching thin film transistor to generate a data current from a power source supplied from the power line and supply the data current to the anode electrode layer 4.

The sensing thin film transistor serves to detect a threshold voltage deviation of the driving thin film transistor, which causes the degradation of image quality, and supplies the current of the driving thin film transistor to the reference line in response to a sensing control signal supplied from the gate line or a separate sensing line.

The capacitor serves to maintain the data voltage supplied to the driving thin film transistor for one frame and is connected to each of a gate terminal and a source terminal of the driving thin film transistor.

A first transistor 31, a second transistor 32, and a third transistor 33 are respectively disposed in the sub-pixels 21, 22, and 23 in the first insulating layer 3a. The first transistor 31 may be connected to the first anode electrode 4a disposed on the first sub-pixel 21 to apply a driving voltage for emitting light of a color corresponding to the first sub-pixel 21.

The second transistor 32 may be connected to the second anode electrode 4b disposed on the second sub-pixel 22 to apply a driving voltage for emitting light of a color corresponding to the second sub-pixel 22.

The third transistor 33 may be connected to the third anode electrode 4c disposed on the third sub-pixel 23 to apply a driving voltage for emitting light of a color corresponding to the third sub-pixel 23.

When receiving the gate signal from the gate line using each of the transistors 31, 32, and 33, each of the first sub-pixel 21, the second sub-pixel 22, and the third sub-pixel 23 supplies a predetermined current to the light-emitting layer according to the data voltage of the data line. Accordingly, the light-emitting layer of each of the first sub-pixel 21, the second sub-pixel 22, and the third sub-pixel 23 may emit light with a predetermined brightness according to the predetermined current.

The first insulating layer 3a may protect the transistors 31, 32, and 33. The first insulating layer 3a may be formed of an inorganic insulating material, but is not necessarily limited thereto and may be formed of an organic insulating material. The transistors 31, 32, and 33 may be located in the first insulating layer 3a. For example, the first insulating layer 3a may be formed of an inorganic material, such as silicon nitride (SiNₓ), silicon oxide (SiOₓ), aluminum oxide (Al₂O₃), etc., but the embodiments of the present specification are not limited thereto.

The second insulating layer 3b may be disposed on the first insulating layer 3a. For example, the second insulating layer 3b may be formed of an inorganic material, such as silicon nitride (SiNₓ), silicon oxide (SiOₓ), aluminum oxide (Al₂O₃), etc., but the embodiments of the present specification are not limited thereto.

The third insulating layer 3c may be disposed on the second insulating layer 3b. For example, the third insulating layer 3c may be formed of an inorganic material, such as silicon nitride (SiNₓ), silicon oxide (SiOₓ), aluminum oxide (Al₂O₃), etc., but the embodiments of the present specification are not limited thereto.

However, the present specification is not limited thereto, and an additional insulating layer may be further disposed between the insulating layers 3a, 3b, and 3c.

In the first sub-pixel 21, the first insulating layer 3a, the first transistor 31 disposed in the first insulating layer 3a, a first reflective electrode 42a disposed on the first insulating layer 3a, the second insulating layer 3b disposed on the first reflective electrode 42a, a second connection electrode CE2 disposed on the second insulating layer 3b, the third insulating layer 3c disposed on the second connection electrode CE2, a third connection electrode CE3 disposed on the third insulating layer 3c, the first anode electrode 4a disposed on the third connection electrode CE3, and the protective layer PS disposed on the first anode electrode 4a may be disposed sequentially on the substrate 2.

In the first sub-pixel 21, the first reflective electrode 42a may be patterned and disposed across the first light-emitting area EA1 and the first non-light-emitting area NEA1. In the first sub-pixel 21, the second connection electrode CE2 and the third connection electrode CE3 may be patterned and disposed in the first non-light-emitting area NEA1.

In the second sub-pixel 22, the first insulating layer 3a, the first transistor 31 disposed in the first insulating layer 3a, the first connection electrode CE1 disposed on the first insulating layer 3a, the second insulating layer 3b disposed on the first connection electrode CE1, a second reflective electrode 42b disposed on the second insulating layer 3b, the third insulating layer 3c disposed on the second reflective electrode 42b, the third connection electrode CE3 disposed on the third insulating layer 3c, the second anode electrode 4b disposed on the third connection electrode CE3, and the protective layer PS disposed on the second anode electrode 4b may be disposed sequentially on the substrate 2.

In the second sub-pixel 22, the second reflective electrode 42b may be patterned and disposed across the second light-emitting area EA2 and the second non-light-emitting area NEA2. In the second sub-pixel 22, the first connection electrode CE1 and the third connection electrode CE3 may be patterned and disposed in the second non-light-emitting area NEA2.

In the third sub-pixel 23, the first insulating layer 3a, the first transistor 31 disposed in the first insulating layer 3a, the first connection electrode CE1 disposed on the first insulating layer 3a, the second insulating layer 3b disposed on the first connection electrode CE1, the second connection electrode CE2 disposed on the second insulating layer 3b, the third insulating layer 3c disposed on the second connection electrode CE2, a third reflective electrode 42c disposed on the third insulating layer 3c, the third anode electrode 4c disposed on the third reflective electrode 42c, and the protective layer PS disposed on the third anode electrode 4c may be disposed sequentially on the substrate 2.

In the third sub-pixel 23, the third reflective electrode 42c may be patterned and disposed across the third light-emitting area EA3 and the third non-light-emitting area NEA3. In the third sub-pixel 23, the first connection electrode CE1 and the second connection electrode CE2 may be patterned and disposed in the third non-light-emitting area NEA3.

The first reflective electrode 42a disposed in the first sub-pixel 21 and the first connection electrode CE1 disposed in the second sub-pixel 22 and the third sub-pixel 23 may each be disposed separately, but may be formed on the same layer, may include the same material, and may be formed by the same process, but are not limited thereto.

The second reflective electrode 42b disposed in the second sub-pixel 22 and the second connection electrode CE2 disposed in the first sub-pixel 21 and the third sub-pixel 23 may each be disposed separately, but may be formed on the same layer, may include the same material, and may be formed by the same process, but are not limited thereto.

The third reflective electrode 42c disposed in the third sub-pixel 23 and the third connection electrode CE3 disposed in the first sub-pixel 21 and the second sub-pixel 22 may each be disposed separately, but may be formed on the same layer, may include the same material, and may be formed by the same process, but are not limited thereto.

In the non-light-emitting areas NEA1, NEA2, and NEA3, the contact hole CT (CT1 to CT9) may be defined by passing through the first to third insulating layers 3a to 3c in the thickness direction, and in the sub-pixels 21, 22, and 23, the contact holes CT (CT1 to CT9) may electrically connect the transistors 31, 32, and 33 to the anode electrodes layer 4 (4a, 4b, and 4c).

A first contact hole CT1 may be defined by the first insulating layer 3a in the first light-emitting area EA1. The first contact hole CT1 may pass through the first insulating layer 3a in the thickness direction (the third direction DR3) to expose the first transistor 31. In the first light-emitting area EA1, the first reflective electrode 42a may come into contact with the first transistor 31 through the first contact hole CT1.

A second contact hole CT2 may be defined by the second insulating layer 3b in the first light-emitting area EA1. The second contact hole CT2 may pass through the second insulating layer 3b in the thickness direction (the third direction DR3) to expose the first reflective electrode 42a. In the first light-emitting area EA1, the second connection electrode CE2 may come into contact with the first reflective electrode 42a through the second contact hole CT2.

A third contact hole CT3 may be defined by the third insulating layer 3c in the first light-emitting area EA1. The third contact hole CT3 may pass through the third insulating layer 3c in the thickness direction (the third direction DR3) to expose the second connection electrode CE2. In the first light-emitting area EA1, the third connection electrode CE3 may come into contact with the second connection electrode CE2 through the third contact hole CT3.

A fourth contact hole CT4 may be defined by the first insulating layer 3a in the second light-emitting area EA2. The fourth contact hole CT4 may pass through the first insulating layer 3a in the thickness direction (the third direction DR3) to expose the second transistor 32. In the second light-emitting area EA2, the first connection electrode CE1 may come into contact with the second transistor 32 through the fourth contact hole CT4.

A fifth contact hole CT5 may be defined by the second insulating layer 3b in the second light-emitting area EA2. The fifth contact hole CT5 may pass through the second insulating layer 3b in the thickness direction (the third direction DR3) to expose the first connection electrode CE1. In the second light-emitting area EA2, the second reflective electrode 42b may come into contact with the first connection electrode CE1 through the fifth contact hole CT5.

A sixth contact hole CT6 may be defined by the third insulating layer 3c in the second light-emitting area EA2. The sixth contact hole CT6 may pass through the third insulating layer 3c in the thickness direction (the third direction DR3) to expose the second reflective electrode 42b. In the second light-emitting area EA2, the third connection electrode CE3 may come into contact with the second reflective electrode 42b through the sixth contact hole CT6.

A seventh contact hole CT7 may be defined by the first insulating layer 3a in the third light-emitting area EA3. The seventh contact hole CT7 may pass through the first insulating layer 3a in the thickness direction (the third direction DR3) to expose the third transistor 33. In the third light-emitting area EA3, the first connection electrode CE1 may come into contact with the third transistor 33 through the seventh contact hole CT7.

An eighth contact hole CT8 may be defined by the second insulating layer 3b in the third light-emitting area EA3. The eighth contact hole CT8 may pass through the second insulating layer 3b in the thickness direction (the third direction DR3) to expose the first connection electrode CE1. In the third light-emitting area EA3, the second connection electrode CE2 may come into contact with the first connection electrode CE1 through the eighth contact hole CT8.

A ninth contact hole CT9 may be defined by the third insulating layer 3c in the third light-emitting area EA3. The ninth contact hole CT9 may pass through the third insulating layer 3c in the thickness direction (the third direction DR3) to expose the second connection electrode CE2. In the third light-emitting area EA3, the third reflective electrode 42c may come into contact with the second connection electrode CE2 through the ninth contact hole CT9.

As described above, the transistors 31, 32, and 33, the connection electrodes CE1, CE2, and CE3, and the reflective electrodes 42a, 42b, and 42c have been described as coming into direct contact with one another through the contact holes CT (CT1 to CT9), but the embodiments of the present specification are not limited thereto. For example, each contact hole CT (CT1 to CT9) may be filled with a separate contact layer (not illustrated), and the transistors 31, 32, and 33, the connection electrodes CE1, CE2, and CE3, and the reflective electrodes 42a, 42b, and 42c may be electrically connected by contact layers filling the contact holes CT (CT1 to CT9). Here, the contact layer (not illustrated) may be formed of tungsten etc.

The reflective electrodes 42a, 42b, and 42c may reflect light, which is emitted toward the reflective electrode 42 among light emitted from the common light-emitting layer 5 of each sub-pixel 21, 22, or 23, toward the cathode electrode 6 or the encapsulation layer 8. In addition, the reflective electrode 42 is formed to implement the micro-cavity characteristic through reflection and re-reflection with the cathode electrode 6. To this end, the reflective electrode 42 may include a reflective material for reflecting light. For example, the reflective material may be a metal, but is not necessarily limited thereto, and may be any other material as long as it may reflect light. For example, the reflective material may include titanium (Ti)/aluminum (Al), but is not limited thereto.

The display apparatus 1 according to one embodiment may be provided in the top emission type, and to this end, the reflective electrode 42 may be provided to reflect the light emitted from the common light-emitting layer 5 upward.

The reflective electrode 42 may reflect light, which is emitted toward the reflective electrode 42 among the light emitted from the common light-emitting layer 5 of each sub-pixel 21, 22, or 23, toward the cathode electrode 6 or the encapsulation layer 8. In addition, the reflective electrode 42 is formed to implement the micro-cavity characteristic through reflection and re-reflection with the cathode electrode 6. To this end, the reflective electrode 42 may include a reflective material for reflecting light.

Since the reflective electrode 42 is disposed at a relatively lower location than the common light-emitting layer 5 for emitting light, the reflective electrode 42 may reflect the light emitted from the common light-emitting layer 5 upward. Here, upward may refer to a direction in which a user may perceive light, for example, a side to which the encapsulation layer 8 or the color filter layer 9 is disposed. Accordingly, it is possible to further increase the light efficiency of the first sub-pixel 21, the second sub-pixel 22, and the third sub-pixel 23 compared to a case in which there is no reflective electrode 42, and the user can perceive an image with high brightness, that is, clear image, through the increased light efficiency. That is, the user can perceive a clear image.

As described above, the display apparatus 1 may have the reflective electrode 42, thereby further increasing the light extraction efficiency using the micro-cavity characteristic. The reflective electrode 42 may include the first reflective electrode 42a, the second reflective electrode 42b, and the third reflective electrode 42c.

A distance between the first reflective electrode 42a and the anode electrode layer 4 may be larger than a distance between the second reflective electrode 42b and the anode electrode layer 4. A distance between the second reflective electrode 42b and the anode electrode layer 4 may be larger than a distance between the third reflective electrode 42c and the anode electrode layer 4.

The cathode electrodes 6 in the light-emitting area EA1, EA2, or EA3 of the sub-pixel 21, 22, or 23 may be located colinearly. Accordingly, a size relationship between the distance between the reflective electrodes 42a, 42b, or 42c and the anode electrode layer 4 in each sub-pixel 21, 22, or 23 may be the same as a size relationship between the distance between the reflective electrode 42a, 42b, or 42c and the cathode electrode 6.

In this way, the reason why the reflective electrodes 42a, 42b, and 42c are formed to have various spacing distances (or resonance distances) from the cathode electrode 6 is that the light extraction efficiency of different colors can be increased through reflection and re-reflection between the reflective electrodes 42a, 42b, and 42c and the cathode electrode 6 according to the spacing distances. Accordingly, it is possible to increase the light extraction efficiency of red light in the first sub-pixel 21, increase the light extraction efficiency of green or blue light in the second sub-pixel 22, and increase the light extraction efficiency of blue or green light in the third sub-pixel 23.

The connection electrodes CE1, CE2, and CE3 may be disposed in the light-emitting areas EA1, EA2, and EA3 of the sub-pixels 21, 22, and 23. The connection electrodes CE1, CE2, and CE3 may be disposed on the same layer as the reflective electrodes 42a, 42b, and 42c and formed through the same process as the reflective electrodes 42a, 42b, and 42c.

The anode electrode layer 4 is disposed on the reflective electrode 42. The anode electrode layer 4 is formed to supply holes to the common light-emitting layer 5. The anode electrode layer 4 may be provided transparently so that light reflected from the reflective electrode 42 may proceed upward. The anode electrode layer 4 may be formed of a transparent material, but is not limited thereto, and a metal material may be formed in the form of a thin film as long as it may transmit light. For example, the anode electrode layer 4 may include titanium nitride (TiN), but is not limited thereto. The anode electrode layer 4 may be formed of a very thin film so that the light reflected from the reflective electrode 42 may proceed upward. For example, the thickness of the anode electrode layer 4 may be about 5 nm or less. For example, the thickness of the anode electrode layer 4 may be about 3 nm or less, but is not limited thereto.

The anode electrode layer 4 may come into direct contact with the reflective electrode 42 and may be electrically connected to the reflective electrode 42 or may be indirectly connected to the reflective electrode 42 through the contact hole CT and electrically connected to the reflective electrode 42. The reflective electrode 42 may be electrically connected to each of the first to third transistors 31, 32, and 33 through another contact hole CT so that a driving voltage provided by each of the first to third transistors 31, 32, and 33 may be applied to the anode electrode layer 4. The anode electrode layer 4 may supply holes to the common light-emitting layer 5 when the driving voltages are applied from the first to third transistors 31, 32, and 33. In each sub-pixel 21, 22, or 23, the anode electrode layer 4 may come into direct contact with the third reflective electrode 42c.

The anode electrode layer 4 may be disposed in each of the first to third sub-pixels 21, 22, and 23 to have substantially the same height from an upper surface of the reflective electrode 42, the connection electrode CE, or the insulating layer 3.

The protective layer PS may be disposed on the anode electrode layer 4 (4a, 4b, and 4c). The protective layer PS may be formed of an inorganic material, such as silicon nitride (SiNₓ), silicon oxide (SiOₓ), aluminum oxide (Al₂O₃), etc., but the embodiments of the present specification are not limited thereto.

In the light-emitting areas EA1, EA2, and EA3, the protective layer PS may define the light-emitting areas EA1, EA2, and EA3 by exposing upper surfaces of the anode electrode layer 4 (4a, 4b, and 4c). On the other hand, in the non-light-emitting areas NEA1, NEA2, and NEA3, the protective layer PS may cover the upper surfaces of the anode electrode layers 4a, 4b, and 4c.

The common light-emitting layer 5 is formed on the anode electrode layer 4 and the protective layer PS. The common light-emitting layer 5 may also be formed on the filling members 10 disposed between the plurality of sub-pixels 21, 22, and 23. The common light-emitting layer 5 may come into contact with the upper surface of the anode electrode layer 4. The common light-emitting layer 5 may come into direct contact with the side surface and upper surface of the protective layer PS.

The OLED according to one embodiment may include the anode electrode layer 4 or ANO, the cathode electrode 6 or CAT, and the common light-emitting layer 5 between the anode electrode layer 4 and the cathode electrode 6.

The common light-emitting layer 5 may be provided to emit white (W) light. To this end, the common light-emitting layer 5 may include a plurality of stacks for emitting light of different colors. Specifically, the common light-emitting layer 5 may include a first stack, a second stack, and a charge generation layer CGL provided between the first stack and the second stack.

The cathode electrode 6 is formed on the common light-emitting layer 5. The cathode electrode 6 may serve as a cathode of the display apparatus 1. Like the common light-emitting layer 5, the cathode electrode 6 is formed in each of the sub-pixels 21, 22, and 23 and between the sub-pixels 21, 22, and 23.

In the display apparatus 1 according to one embodiment, the cathode electrode 6 may be formed as a cathode electrode including a translucent material in order to implement white light with increased light efficiency in the top emission type. Accordingly, the micro-cavity effect can be obtained for each of the first to third sub-pixels 21, 22, and 23. When the cathode electrode 6 is formed as the cathode electrode including a translucent material, the micro-cavity effect can be obtained as light is reflected and re-reflected repeatedly between the cathode electrode 6 and the reflective electrode 42, thereby increasing light extraction efficiency.

Meanwhile, since the cathode electrode 6 is formed on the upper surface of the common light-emitting layer 5, the cathode electrode 6 may be formed along a profile of the common light-emitting layer 5. Since the common light-emitting layer 5 is formed along the profile of the anode electrode layer 4 in the light-emitting area, the cathode electrode 6 may be formed along the profile of the anode electrode layer 4. In addition, the capping layer 7 on the cathode electrode 6 may also be formed along a profile of the cathode electrode 6.

The capping layer 7 may be formed of an inorganic insulating material, but is not limited thereto. The capping layer 7 may be formed of a single layer, but is not limited thereto, and may be formed of multiple layers. The capping layer 7 may be disposed on the cathode electrode 6 to protect the OLED.

The encapsulation layer 8 is formed on the cathode electrode 6 to prevent or at least reduce external moisture from penetrating the common light-emitting layer 5. The encapsulation layer 8 may be formed of an inorganic insulating material or formed in a structure in which an inorganic insulating material and an organic insulating material are alternately stacked, but is not necessarily limited thereto.

The color filter layer 9 is formed on the encapsulation layer 8. The color filter layer 9 may include the red (R) first color filter 91 provided in the first sub-pixel 21, the blue (G) second color filter 92 provided in the second sub-pixel 22, and the green (B) third color filter 93 provided in the third sub-pixel 23, but is not necessarily limited thereto.

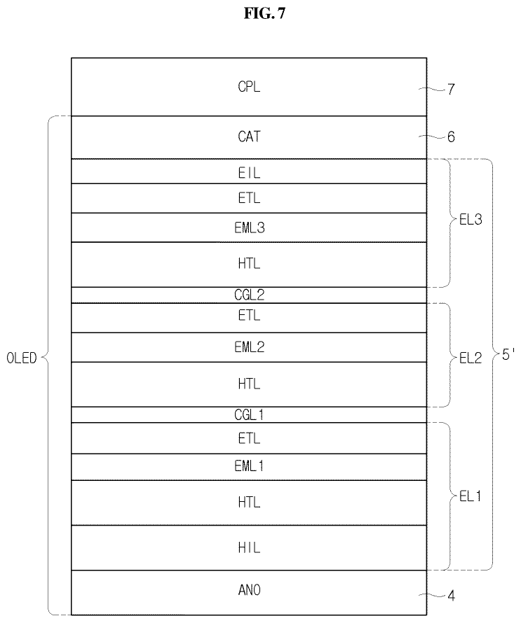

FIG. 6 is a cross-sectional view of an organic light-emitting diode (OLED) according to FIG. 2 according to one embodiment. FIG. 7 is a cross-sectional view of an OLED according to a modified example of FIG. 2 according to one embodiment.

Referring to FIGS. 1 to 6, the common light-emitting layer 5 may include the first stack EL1, the second stack EL2, and the first charge generation layer CGL1, which are provided on the anode electrode layer 4.

The first stack EL1 may be provided on the anode electrode layer 4 and configured in a structure in which a hole injecting layer HIL, a hole transporting layer HTL, a blue (B) emitting layer EML1, and an electron transporting layer ETL may be stacked sequentially.

The first stack EL1 may be disposed between the first sub-pixel 21 and the second sub-pixel 22 and between the second sub-pixel 22 and the third sub-pixel 23.

The first charge generation layer CGL1 serves to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may include a metal material as a dopant.

The second stack EL2 may be provided on the first stack EL1 and configured in a structure in which a hole transporting layer HTL, a yellow green (YG) emitting layer EML2, an electron transporting layer ETL, and an electron injecting layer EIL are stacked sequentially.

The second stack EL2 may be disposed between the first sub-pixel 21 and the second sub-pixel 22 and between the second sub-pixel 22 and the third sub-pixel 23.

As a result, the common light-emitting layer 5 may be provided as a common layer across the first to third sub-pixels 21, 22, and 23 or across adjacent sub-pixels as illustrated in FIGS. 3 and 4.

As shown in FIG. 7, a common light-emitting layer 5′ of the OLED according to one embodiment may include the first stack EL1 provided on the anode electrode layer 4, the second stack EL2, a third stack EL3, the first charge generation layer CGL1 between the first stack EL1 and the second stack EL2, and a second charge generation layer CGL2 between the second stack EL2 and the third stack EL3.

The first stack EL1 may be provided on the anode electrode layer 4 and configured in a structure in which a hole injecting layer HIL, a hole transporting layer HTL, a blue (B) emitting layer EML1, and an electron transporting layer ETL may be stacked sequentially.

The first stack EL1 may be disposed between the first sub-pixel 21 and the second sub-pixel 22 and between the second sub-pixel 22 and the third sub-pixel 23, that is, on a bank.

The first charge generation layer CGL1 serves to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may include a metal material as a dopant.

The second stack EL2 may be provided on the first stack EL1 and configured in a structure in which a hole transporting layer HTL, a green (G) emitting layer EML2, an electron transporting layer ETL are stacked sequentially.

The second stack EL2 may be disposed between the first sub-pixel 21 and the second sub-pixel 22 and disposed between the second sub-pixel 22 and the third sub-pixel 23, that is, on the bank.

The second charge generation layer CGL2 functions to supply charges to the second stack EL2 and the third stack EL3. The second charge generation layer CGL2 may include an N-type charge generation layer for supplying electrons to the second stack EL2 and a P-type charge generation layer for supplying holes to the third stack EL3. The N-type charge generation layer may include a metal material as a dopant.

The third stack EL3 may be provided on the second stack EL2 and configured in a structure in which a hole transporting layer HTL, a red (R) emitting layer EML3, an electron transporting layer ETL, and an electron injecting layer EIL are stacked sequentially.

Referring to FIGS. 1 to 7, in the display apparatus 1, since the common light-emitting layer 5 is also disposed between the sub-pixels 21, 22, and 23, when one sub-pixel emits light, a lateral leakage current may flow to the adjacent sub-pixels 21, 22, and 23 through the charge generation layers CGL1 and CGL2. However, since the common light-emitting layer 5 may be separated at the boundary of the sub-pixels 21, 22, and 23 through the trench TR disposed between the sub-pixels 21, 22, and 23, it is possible to prevent a lateral leakage current and light color mixing.

Furthermore, even when the intersection trench TRO has the second width W2 greater than the first widths W1 of the first trench TRH and the second trench TRV, since the inside of the intersection trench TRO may be partially filled with the filling member 10 to separate the common light-emitting layer 5, it is possible to prevent a lateral leakage current and a short circuit between the charge generation layers CGL1 and CGL2 and the cathode electrode 6, thereby preventing light color mixing.

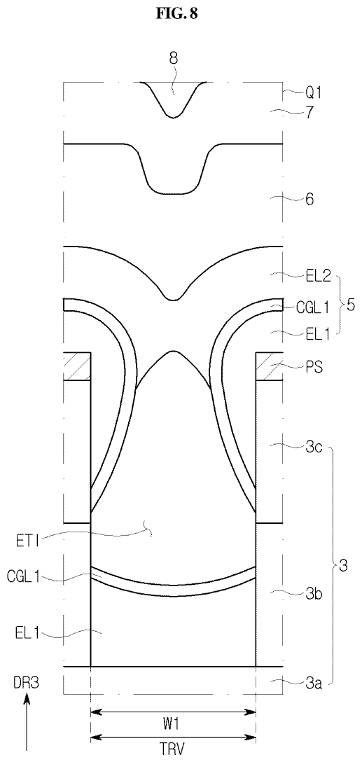

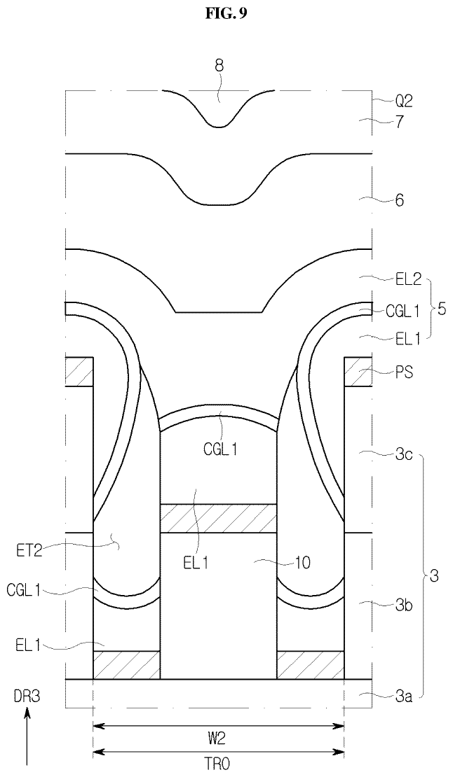

Detailed description thereof will be given with reference to FIGS. 8 and 9. In addition, for convenience of description, the following description will be given based on the common light-emitting layer 5 of FIG. 6, but the corresponding description may also be applied to the common light-emitting layer 5′ of FIG. 7 in the same manner.

FIG. 8 is an enlarged view of area Q1 in FIG. 2 according to one embodiment. FIG. 9 is an enlarged view of area Q2 in FIG. 5 according to one embodiment.

FIG. 8 illustrates a cross section around the second trench TRV, and FIG. 9 illustrates a cross section around the intersection trench TRO. FIG. 8 illustrates the cross section around the second trench TRV, and hereinafter, the second trench TRV will be described, but the description of the second trench TRV may also be applied to the first trench TRH in the same manner.

First, referring to FIGS. 1 to 8, the second trench TRV may have a groove or recess shape including a floor surface and side surfaces. The floor surface of the second trench TRV may be formed of the first insulating layer 3a, but is not limited thereto, and the floor surface of the second trench TRV may be formed of the second insulating layer 3b. The side surface of the second trench TRV may be formed of the second insulating layer 3b and the third insulating layer 3c. However, the embodiments of the present specification are not limited thereto, and the side surface of the second trench TRV may further include the protective layer PS.

The second trench TRV may have the first width W1.

The common light-emitting layer 5 may be deposited in a state in which the trench TR is formed. The first stack EL1 is disposed on the anode electrode layer 4 and the protective layer PS.

The first stack EL1 may be disposed across all areas of the sub-pixels 21, 22, and 23 and may also be disposed in the trench TR structure. A part of the first stack EL1 may be disposed inside the second trench TRV.

The first stack EL1 disposed inside the second trench TRV may extend from the first stack EL1 disposed on the anode electrode layer 4 and the protective layer PS and may be partially disposed on the side surfaces of the second trench TRV. In addition, the first stack EL1 disposed inside the second trench TRV may be disposed on the floor surface of the second trench TRV (e.g., the first insulating layer 3a exposed by the trench TR). The first stack EL1 disposed on the floor surface of the second trench TRV may be separated from the first stack EL1 disposed on the anode electrode layer 4 and the protective layer PS and the first stack EL1 disposed on the side surfaces of the second trench TRV. Accordingly, the first stack EL1 disposed in each sub-pixel 21, 22, or 23 may be disposed separately for each sub-pixel 21, 22, or 23.

The first charge generation layer CGL1 may be disposed on the first stack EL1. The first charge generation layer CGL1 may be disposed in substantially the same area as the first stack EL1, but is not limited thereto. A part of the first charge generation layer CGL1 may be disposed in the second trench TRV. The first charge generation layer CGL1 disposed in the second trench TRV may be separated from the first charge generation layer CGL1 disposed on the anode electrode layer 4 and the protective layer PS and the first charge generation layer CGL1 disposed on the side surfaces of the second trench TRV. Accordingly, the first charge generation layer CGL1 disposed in each sub-pixel 21, 22, or 23 may be disposed separately for each sub-pixel 21, 22, or 23.

Although not illustrated, a part of the protective layer PS may be disposed separately inside the second trench TRV. The protective layer PS disposed inside the second trench TRV may be disposed under the first stack EL1 disposed inside the second trench TRV.

The second stack EL2 may be disposed on the first charge generation layer CGL1. The second stack EL2 may be disposed to cover an upper portion of the second trench TRV. The second stack EL2 may be disposed integrally across the sub-pixels 21, 22, and 23 and the second trench TRV without separated in the area in which the second trench TRV is disposed. The second stack EL2 may be continuous on the trench TR.

The first stack EL1 and the first charge generation layer CGL1 that are disposed on the anode electrode layer 4 may extend so that parts of the first stack EL1 and the first charge generation layer CGL1 protrude inward of the second trench TRV and may further extend to be disposed on the side surfaces of the second trench TRV. In the adjacent sub-pixels 21, 22, and 23, the first stack EL1 and the first charge generation layer CGL1 that extend and protrude toward the second trench TRV may have a gap smaller than the first width W1. Accordingly, the second stack EL2 may be disposed to cover the second trench TRV without penetrating the second trench TRV.

Accordingly, a first void ET1 that is not filled with a material may be formed inside the second trench TRV. The first void ET1 may be defined by the side surfaces of the second trench TRV, the first stack EL1, the first charge generation layer CGL1, the second stack EL2, etc., but is not limited thereto.

The cathode electrode 6 may be disposed on the second stack EL2. The cathode electrode 6 may be disposed integrally across the sub-pixels 21, 22, and 23 and the second trench TRV without separated in the area in which the second trench TRV is disposed.

Even when the common light-emitting layer 5 is disposed across the sub-pixels 21, 22, and 23, since the first charge generation layer CGL1 may be separated in each sub-pixel 21, 22, or 23 through the second trench TRV, it is possible to prevent a leakage current between the adjacent sub-pixels 21, 22, and 23, thereby suppressing or preventing light color mixing.

In addition, even when the second trench TRV is disposed, the second stack EL2 may be integrally disposed across the sub-pixels 21, 22, and 23 and the second trench TRV. Accordingly, the second stack EL2 may cover the first charge generation layer CGL1 and prevent the cathode electrode 6 from coming into contact with the first charge generation layer CGL1 to cause a short circuit defect.

Referring further to FIG. 9, the intersection trench TRO may have the second width W2 greater than the first widths W1 of the first trench TRH and the second trench TRV. The intersection trench TRO in which the first trench TRH and the second trench TRV intersect may be over-etched so that the intersection trench TRO may have the second width W2 greater than the first width W1.

The filling member 10 may be disposed in the intersection trench TRO. As the filling member 10 is disposed, even when the intersection trench TRO is formed to have the second width W2, the first charge generation layer CGL1 between the sub-pixels 21, 22, and 23 may be separated, and a short circuit defect between the first charge generation layer CGL1 and the cathode electrode 6 can be suppressed or prevented.

Specifically, the protective layer PS and the common light-emitting layer 5 may be disposed in a state in which the filling member 10 is disposed in the intersection trench TRO. A part of the protective layer PS may be disposed inside the intersection trench TRO separately from the protective layer PS disposed on the anode electrode layer 4 and the third insulating layer 3c. The separated part of the protective layer PS may be disposed on the filling member 10 and may overlap the filling member 10.

The first stack EL1 may be disposed on the protective layer PS. The first stack EL1 may be disposed across all areas of the sub-pixels 21, 22, and 23 and may also be disposed in the trench TR structure. A part of the first stack EL1 may be disposed inside the intersection trench TRO.

The first stack EL1 disposed inside the intersection trench TRO may extend from the first stack EL1 disposed on the anode electrode layer 4 and the protective layer PS and may be partially disposed on the side surfaces of the intersection trench TRO.

The first stack EL1 disposed inside the intersection trench TRO may be disposed on a floor surface of the intersection trench TRO (e.g., the first insulating layer 3a exposed by the trench TR) or the protective layer PS disposed on the floor surface.

A part of the first stack EL1 disposed inside the intersection trench TRO may be disposed on the filling member 10. The part of the first stack EL1, which is disposed on the filling member 10, may be disposed on the protective layer PS disposed on the filling member 10.

The first stack EL1 disposed on the floor surface of the intersection trench TRO, the first stack EL1 disposed on the filling member 10, the first stack EL1 disposed on the anode electrode layer 4 and the protective layer PS, and the first stack EL1 disposed on the side surfaces of the intersection trench TRO may be separated. At least a part of the first stack EL1 may be separately disposed in the intersection trench TRO. Accordingly, the first stack EL1 disposed in each sub-pixel 21, 22, or 23 may be disposed separately for each sub-pixel 21, 22, or 23.

The first charge generation layer CGL1 may be disposed on the first stack EL1. The first charge generation layer CGL1 may be disposed in substantially the same area as the first stack EL1, but is not limited thereto. A part of the first charge generation layer CGL1 may be disposed in the intersection trench TRO. The first charge generation layer CGL1 disposed in the intersection trench TRO may be separated from the first charge generation layer CGL1 disposed on the anode electrode layer 4 and the protective layer PS and the first charge generation layer CGL1 disposed on the side surfaces of the intersection trench TRO. Accordingly, the first charge generation layer CGL1 disposed in each sub-pixel 21, 22, or 23 may be disposed separately for each sub-pixel 21, 22, or 23.

However, the embodiments of the present specification are not limited thereto, and the protective layer PS disposed inside the intersection trench TRO may be omitted.

The second stack EL2 may be disposed on the first charge generation layer CGL1. The second stack EL2 may be disposed to cover an upper portion of the intersection trench TRO. The second stack EL2 may be disposed integrally across the sub-pixels 21, 22, and 23 and the intersection trench TRO without separated in the area in which the intersection trench TRO is disposed.

As the filling member 10 is disposed inside the intersection trench TRO and the first stack EL1 and the first charge generation layer CGL1 are disposed on the filling member 10, even when the width (the second width W2) of the intersection trench TRO is greater than the first width W1, the second stack EL2 disposed in the intersection trench TRO may cover the upper portion of the intersection trench TRO without separated and may be disposed integrally across the sub-pixels 21, 22, and 23 and the intersection trench TRO.

Specifically, the first stack EL1 and the first charge generation layer CGL1 that are disposed on the anode electrode layer 4 disposed in each sub-pixel 21, 22, or 23 may extend so that parts of the first stack EL1 and the first charge generation layer CGL1 protrude inward of the intersection trench TRO and may further extend to be disposed on the side surfaces of the intersection trench TRO.

The first stack EL1 and the first charge generation layer CGL1, which extend from the first stack EL1 and the first charge generation layer CGL1 that are disposed on the anode electrode layer 4 of the adjacent sub-pixels 21, 22, and 23 and protrude inward of the intersection trench TRO, may have a width that is sufficient for the second stack EL2 to penetrate therebetween.

However, it is possible to prevent or at least reduce the penetration of the second stack EL2 by the filling member 10 disposed in the intersection trench TRO. For example, the first stack EL1 and the first charge generation layer CGL1 may be disposed on the filling member 10, and the first stack EL1 and the first charge generation layer CGL1 that are disposed on the filling member 10 may cover a space in which the second stack EL2 may penetrate.

That is, a gap between the first stack EL1 and the first charge generation layer CGL1 that protrude inward of the intersection trench TRO and the first stack EL1 and the first charge generation layer CGL1 that are disposed on the filling member 10 may not be sufficient for the second stack EL2 to penetrate therebetween. Accordingly, the second stack EL2 is not disposed inside the intersection trench TRO, may cover the intersection trench TRO, and may be disposed integrally across all of the adjacent sub-pixels 21, 22, and 23.

The cathode electrode 6 may be disposed on the second stack EL2. The cathode electrode 6 may be disposed integrally across the sub-pixels 21, 22, and 23 and the intersection trench TRO without separated in the area in which the intersection trench TRO is disposed.

When the second stack EL2 penetrates the intersection trench TRO and is disposed along the first charge generation layer CGL1, the cathode electrode 6 may penetrate the intersection trench TRO along the second stack EL2, and the cathode electrode 6 may come into contact with the first charge generation layer CGL1 to cause a short circuit defect.

By arranging the filling member 10 in each intersection trench TRO, it is possible to prevent the second stack EL2 and the cathode electrode 6 from penetrating the intersection trench TRO, thereby preventing a short circuit defect in which the cathode electrode 6 comes into contact with the first charge generation layer CGL1.

As a result, by arranging the filling member 10 in each intersection trench TRO, even when the intersection trench TRO is over-etched and formed to have a broad width (the second width W2), the first charge generation layer CGL1 may be separated in each sub-pixel 21, 22, or 23 and can prevent a short circuit defect between the cathode electrode 6 and the first charge generation layer CGL1. Accordingly, it is possible to suppress or prevent a leakage current between the sub-pixels 21, 22, and 23 and suppress or prevent light color mixing.

As the filling member 10 is disposed in each intersection trench TRO, a second void ET2 that is not filled with a material may be formed inside the intersection trench TRO. The second void ET2 may be defined by at least one of the side surfaces of the intersection trench TRO, the first stack EL1, the first charge generation layer CGL1, the protective layer PS, the second stack EL2, and the filling member 10, but is not limited thereto.

The second void ET2 may be formed to surround the periphery of the filling member 10, but is not limited thereto. For example, the second void ET2 may be defined as a plurality of voids around the filling member 10.

Hereinafter, a method of manufacturing the display apparatus 1 according to one embodiment will be described. While describing the method of manufacturing the display apparatus 1 according to one embodiment, description of parts already described in FIGS. 1 to 9 will be briefly given or omitted.

Hereinafter, the method of manufacturing the display apparatus 1 will be described through a cross section around the intersection trench TRO between the first sub-pixel 21 and the second sub-pixel 22, but the corresponding description is not limited thereto and may be applied to all intersection trenches TROs and filling members 10 in the same manner.

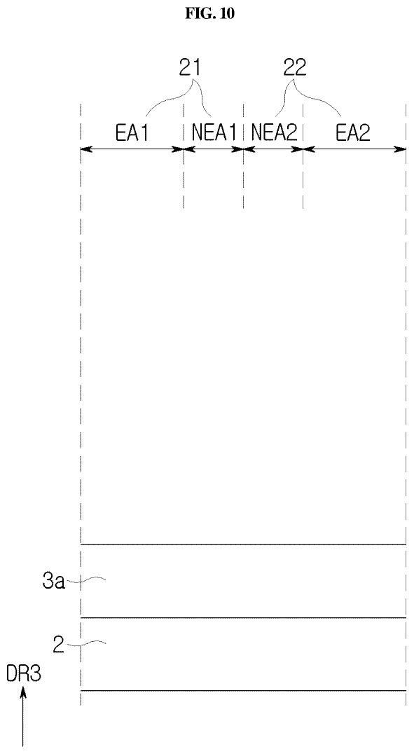

FIGS. 10 to 18 are cross-sectional views for each process in a method of manufacturing a display apparatus according to one embodiment.

Referring to FIGS. 1 to 5 and 10, the substrate 2 capable of supporting other components disposed thereon is provided. The first insulating layer 3a may be disposed on the substrate 2. Circuit elements including the plurality of thin film transistors 31, 32, and 33, various signal lines, capacitors, etc. may be provided in the first insulating layer 3a of each sub-pixel 21, 22, or 23.

The first insulating layer 3a may be disposed on the entire area of the substrate 2, but is not limited thereto.

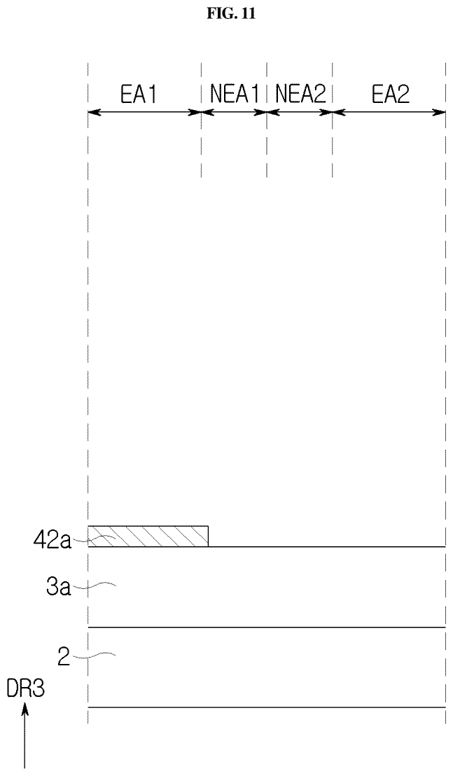

Subsequently, referring further to FIG. 11, the first reflective electrode 42a and the first connection electrode CE1 may be patterned and disposed on the first insulating layer 3a.

Specifically, a first conductive layer (not illustrated) may be disposed on the entire area of the first insulating layer 3a. A patterned first photoresist (not illustrated) may be disposed on the first conductive layer (not illustrated), and the first conductive layer (not illustrated) exposed by the first photoresist (not illustrated) may be removed so that the first reflective electrode 42a and the first connection electrode CE1 may be patterned. The first photoresist (not illustrated) may be removed by an ashing process.

Although not illustrated in FIG. 11, the first connection electrode CE1 may be formed through the same process (or mask) as the first reflective electrode 42a and may include the same material. The first reflective electrode 42 a may be disposed in the first sub-pixel 21, and the first connection electrode CE1 may be disposed in each of the second sub-pixel 22 and the third sub-pixel 23.

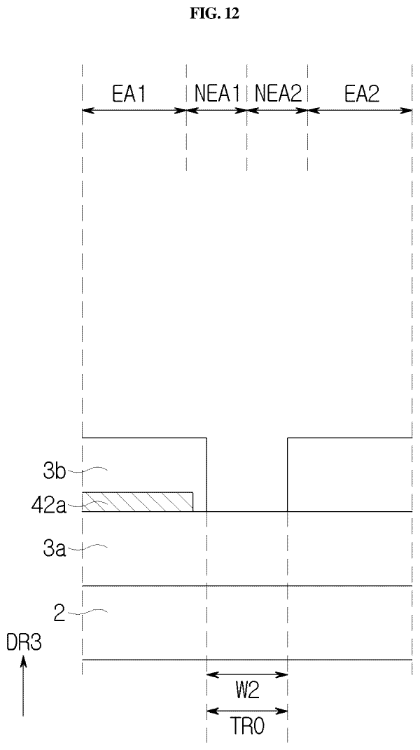

Subsequently, referring further to FIG. 12, the second insulating layer 3b may be disposed on the first reflective electrode 42a and the first connection electrode CE1. The second insulating layer 3b may cover the first reflective electrode 42a and the first connection electrode CE1 and may be disposed on the entire area of the first insulating layer 3a.

A patterned second photoresist (not illustrated) may be disposed on the second insulating layer 3b disposed on the entire area of the first insulating layer 3a, and the second insulating layer 3b in the area exposed by the second photoresist (not illustrated) may be removed to pattern the second insulating layer 3b. The second photoresist (not illustrated) may be removed by an ashing process.

A part of the second insulating layer 3b disposed on the entire area of the first insulating layer 3a may be removed from the area in which the intersection trench TRO is formed to expose the first insulating layer 3a. However, the embodiments of the present specification are not limited thereto, and only some area of the second insulating layer 3b may be recessed in the third direction DR3 without exposing the first insulating layer 3a.

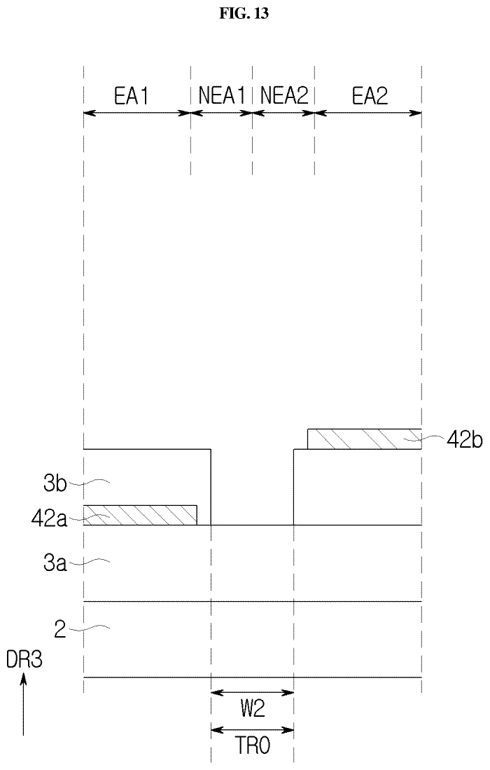

Subsequently, referring further to FIG. 13, the second reflective electrode 42b and the second connection electrode CE2 may be patterned and disposed on the second insulating layer 3b.

Specifically, a second conductive layer (not illustrated) may be disposed on the entire area of the second insulating layer 3b on the second insulating layer 3b. A patterned third photoresist (not illustrated) may be disposed on the second conductive layer (not illustrated), and the second conductive layer (not illustrated) exposed by the third photoresist (not illustrated) may be removed so that the second reflective electrode 42b and the second connection electrode CE2 may be patterned. The third photoresist (not illustrated) may be removed by an ashing process.

Although not illustrated in FIG. 13, the second connection electrode CE2 may be formed through the same process (or mask) as the second reflective electrode 42b and may include the same material. The second reflective electrode 42b may be disposed in the second sub-pixel 22, and the second connection electrode CE2 may be disposed in each of the first sub-pixel 21 and the third sub-pixel 23.

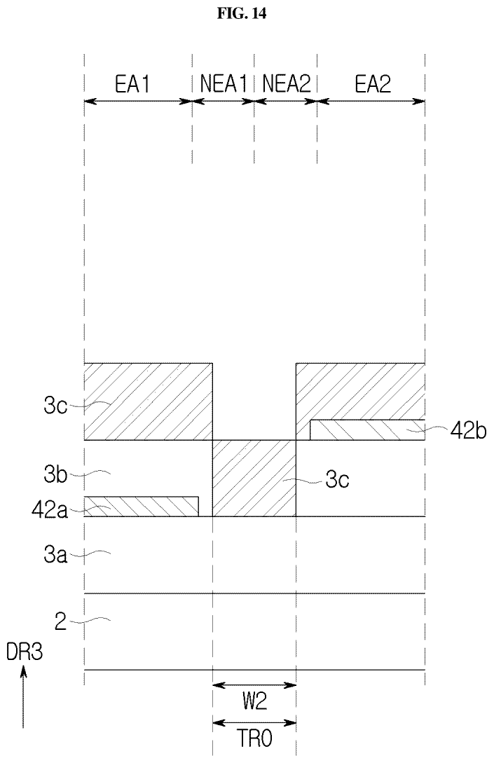

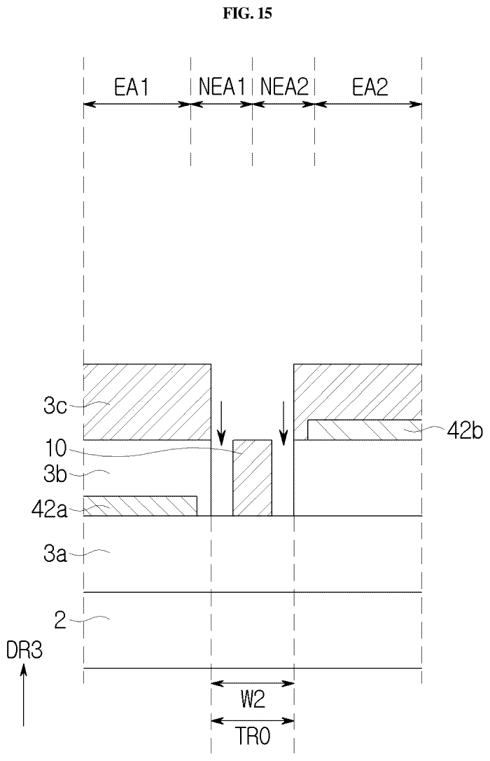

Subsequently, referring further to FIGS. 14 and 15, the third insulating layer 3c may be disposed on the second reflective electrode 42b and the second connection electrode CE2. The third insulating layer 3c may cover the second reflective electrode 42b and the second connection electrode CE2, may be disposed on the second insulating layer 3b, and disposed on the entire area of the first insulating layer 3a, but is not limited thereto.

The third insulating layer 3c may also be disposed in the area in which the intersection trench TRO is formed and may fill a portion of the area in which the intersection trench TRO is formed, in which a part of the second insulating layer 3b is removed.

The third insulating layer 3c disposed in the area in which the intersection trench TRO is formed may be etched and patterned by a separate fourth photoresist (not illustrated) to form the filling member 10. In addition, the intersection trench TRO may be defined by the first insulating layer 3a, the second insulating layer 3b, and the third insulating layer 3c. The filling member 10 may be disposed in the area of the intersection trench TRO.

In this case, the filling member 10 may be formed by the same process (mask) as the third insulating layer 3c and may include the same material as the third insulating layer 3c. The filling member 10 may have the same thickness as the third insulating layer 3c and have a different thickness from the second insulating layer 3b, but is not limited thereto.

During the process of forming the intersection trench TRO or the trench TR, the filling member 10 may be formed through the same mask, and thus an additional mask process may not be needed. Accordingly, even when the filling member 10 is disposed in the intersection trench TRO, it is possible to suppress or prevent an increase in the number of processes and cost.

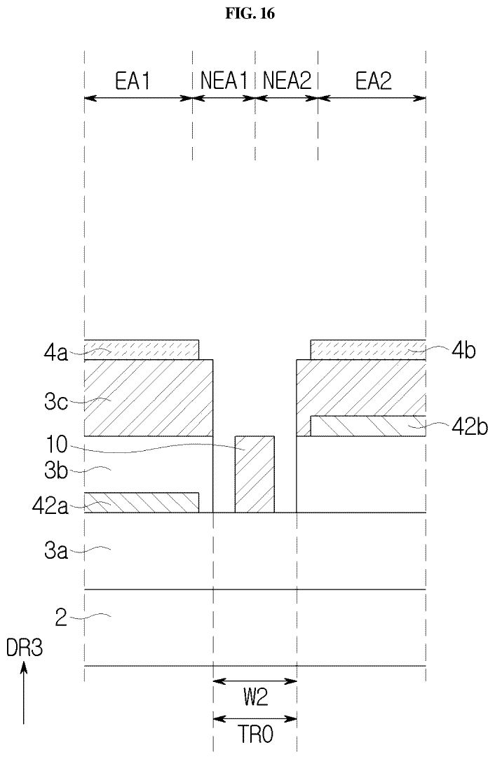

Subsequently, referring further to FIG. 16, the anode electrode layer 4 (4a, 4b, and 4c) may be disposed on the third insulating layer 3c. The anode electrode layer 4 (4a, 4b, and 4 c) may be patterned and disposed in the sub-pixel 21, 22, and 23, respectively.

Specifically, a third conductive layer (not illustrated) may be disposed on the entire area of the third insulating layer 3c on the third insulating layer 3c. A patterned fifth photoresist (not illustrated) may be disposed on the third conductive layer (not illustrated), and the third conductive layer (not illustrated) exposed by the fifth photoresist (not illustrated) may be removed so that the anode electrode layer 4 (4a, 4b, and 4c) may be patterned. The fifth photoresist (not illustrated) may be removed by an ashing process.

Although not illustrated, before the anode electrode layer 4 (4a, 4b, and 4c) is disposed, the third reflective electrode 42c and the third connection electrode CE3 may be patterned and disposed on the third insulating layer 3c. The third reflective electrode 42c and the third connection electrode CE3 may be patterned on the third insulating layer 3c through a process similar to that of the first reflective electrode 42a and the first connection electrode CE1, or the second reflective electrode 42b and the second connection electrode CE2.

The anode electrode layers 4a, 4b, and 4c may be disposed on the third insulating layer 3c while covering the third reflective electrode 42c and the third connection electrode CE3.

For example, in the first sub-pixel 21, the first anode electrode 4a may be disposed on the third connection electrode CE3 in a part of the first non-light-emitting area NEA1 and disposed on the third insulating layer 3c in the first light-emitting area EA1. In the second sub-pixel 22, the second anode electrode 4b may be disposed on the third connection electrode CE3 in a part of the second non-light-emitting area NEA2 and disposed on the third insulating layer 3c in the second light-emitting area EA2. In the third sub-pixel 23, the third anode electrode 4c may be disposed on the third reflective electrode 42c across the third non-light-emitting area NEA3 and the third light-emitting area EA3. However, the embodiments of the present specification are not limited thereto.

The third anode electrode 4c of the third sub-pixel 23 may be disposed at the same height as the first anode electrode 4a of the first sub-pixel 21 and the second anode electrode 4b of the second sub-pixel 22.

Although not illustrated, since some upper area of the third insulating layer 3c disposed in the area of the third sub-pixel 23 may be etched during the patterning process, the third insulating layer 3c may have a reduced thickness. For example, the third insulating layer 3c disposed in the third sub-pixel 23 area may be thinner than the third insulating layer 3c disposed in the first sub-pixel 21 area and the third insulating layer 3c disposed in the second sub-pixel 22 area. For another example, the upper surface of the third insulating layer 3c disposed in the third sub-pixel 23 area may have a lower height than the upper surface of the third insulating layer 3c disposed in the first sub-pixel 21 area and the upper surface of the third insulating layer 3c disposed in the second sub-pixel 22 area.

When some of the third insulating layers 3c disposed in the sub-pixels 21, 22, and 23 have different thicknesses, a half-tone mask may be used during the process of patterning the third insulating layer 3c, but the embodiments of the present specification are not limited thereto.

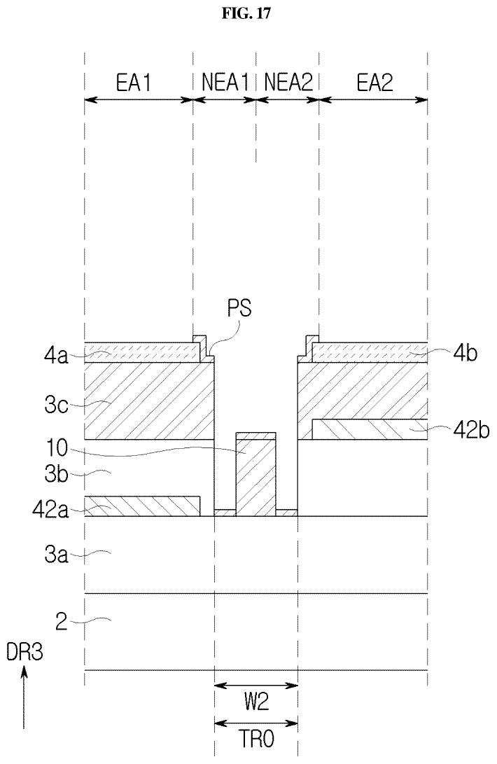

Subsequently, referring further to FIG. 17, the protective layer PS defining the light-emitting areas EA1, EA2, and EA3 may be disposed on the anode electrode layer 4 (4a, 4b, and 4c).

Although not illustrated, the protective layer PS may be disposed on the entire area of the first insulating layer 3a while covering the anode electrode layer 4 (4a, 4b, and 4c). The sixth photoresist (not illustrated) patterned to expose a part of the protective layer PS may be disposed on the protective layer PS disposed on the entire area of the first insulating layer 3a. The protective layer PS exposed by the sixth photoresist (not illustrated) may be etched and removed, and the protective layer PS may be patterned. The sixth photoresist may be removed by an ashing process.

The patterned protective layer PS may expose a part of the anode electrode layer 4 (4a, 4b, or 4c) of each sub-pixel 21, 22, or 23 to define the light-emitting area EA1, EA2, or EA3. A part of the protective layer PS may be disposed in the intersection trench TRO and disposed on the first insulating layer 3a and the filling member 10. The protective layer PS may be disposed between the filling member 10 and the insulating layer, and the protective layer PS between the filling member 10 and the insulating layer may come into direct contact with the first insulating layer 3a.

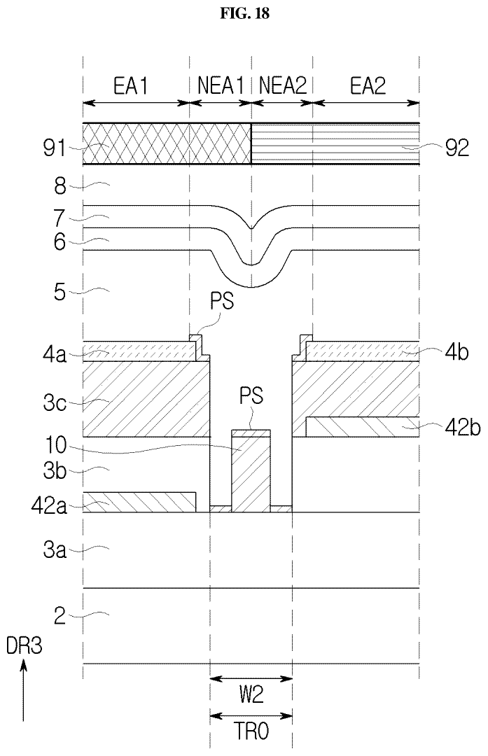

Subsequently, referring further to FIG. 18, the common light-emitting layer 5, the cathode electrode 6, the capping layer 7, the encapsulation layer 8, and the color filter layer 9 may be sequentially stacked on the anode electrode layer 4 (4a, 4b, and 4c) and the protective layer PS.

The common light-emitting layer 5, the cathode electrode 6, the capping layer 7, the encapsulation layer 8, and the color filter layer 9 may be integrally disposed on the entire area of the substrate 2 without distinction between the sub-pixels 21, 22, and 23.

Since the filling member 10 is disposed in each intersection trench TRO, even when the intersection trench TRO has the second width W2 greater than the first width W1, the filling member 10 may fill a part of the intersection trench TRO. Accordingly, the first stack EL1 (see FIG. 6) and the first charge generation layer CGL1 (see FIG. 6) are separated in each sub-pixel 21, 22, or 23, and the entire area of the first charge generation layer CGL1 (see FIG. 6) may be covered by the second stack EL2 (see FIG. 6). That is, the second stack EL2 (see FIG. 6) may be disposed between the first charge generation layer CGL1 (see FIG. 6) and the cathode electrode 6.

It is possible to prevent or at least reduce a leakage current between the adjacent sub-pixels 21, 22, and 23, prevent a short circuit between the charge generation layer CGL1 and the cathode electrode 6, and prevent light color mixing.

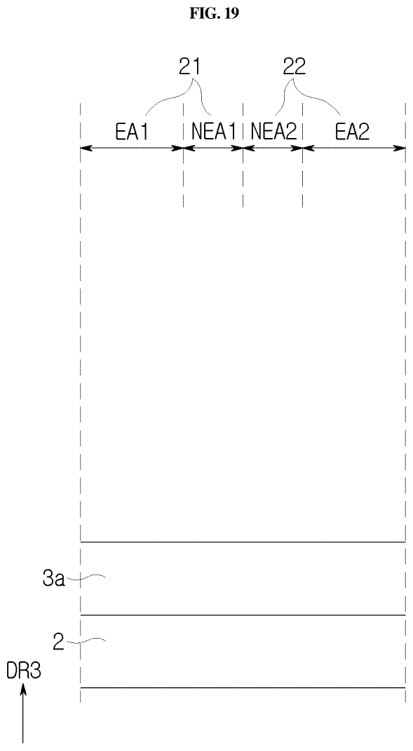

FIGS. 19 to 28 are cross-sectional views for each process in a method of manufacturing a display apparatus according to another embodiment.

Referring to FIGS. 1 to 5 and 19, the substrate 2 capable of supporting other components disposed thereon is provided. The first insulating layer 3a may be disposed on the substrate 2. Circuit elements including the plurality of thin film transistors 31, 32, and 33, various signal lines, capacitors, etc. may be provided in the first insulating layer 3a of each sub-pixel 21, 22, or 23.

The first insulating layer 3a may be disposed on the entire area of the substrate 2, but is not limited thereto.

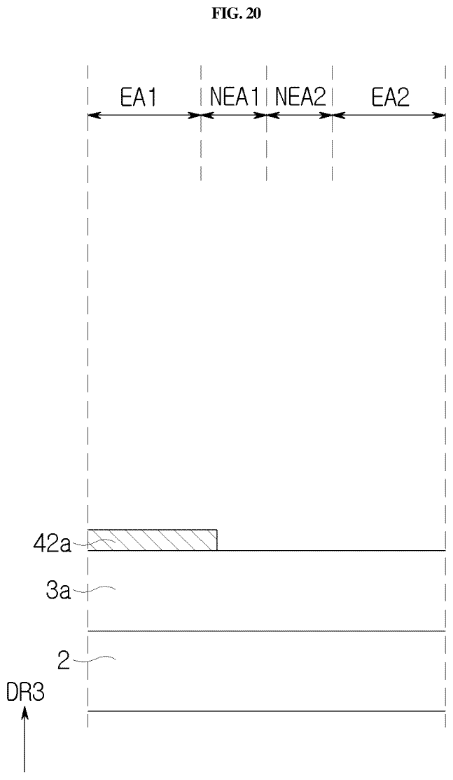

Subsequently, referring further to FIG. 20, the first reflective electrode 42a and the first connection electrode CE1 may be patterned and disposed on the first insulating layer 3a.

Specifically, a first conductive layer (not illustrated) may be disposed across the entire area of the first insulating layer 3a. A patterned first photoresist (not illustrated) may be disposed on the first conductive layer (not illustrated), and the first conductive layer (not illustrated) exposed by the first photoresist (not illustrated) may be removed so that the first reflective electrode 42a and the first connection electrode CE1 may be patterned. The first photoresist (not illustrated) may be removed by an ashing process.

Although not illustrated in FIG. 20, the first connection electrode CE1 may be formed through the same process (or mask) as the first reflective electrode 42a and may include the same material. The first reflective electrode 42a may be disposed in the first sub-pixel 21, and the first connection electrode CE1 may be disposed in each of the second sub-pixel 22 and the third sub-pixel 23.

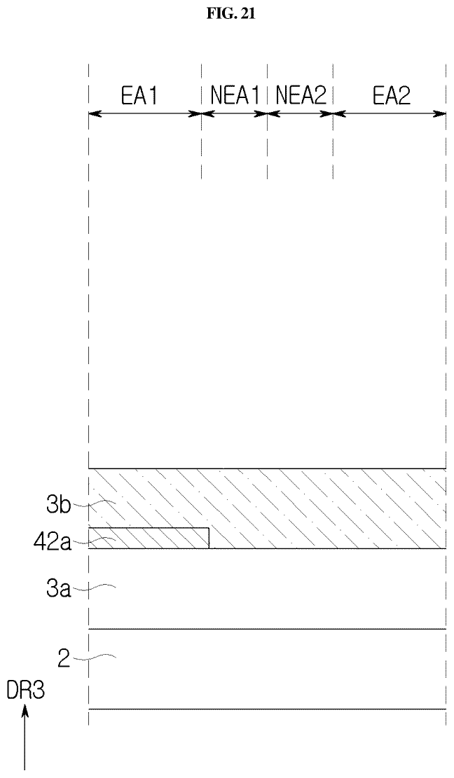

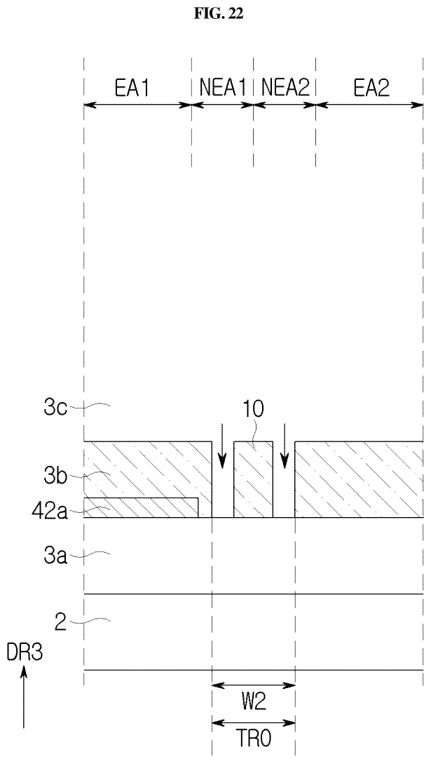

Subsequently, referring further to FIGS. 21 and 22, the second insulating layer 3b may be disposed on the first reflective electrode 42a and the first connection electrode CE1. The second insulating layer 3b may cover the second reflective electrode 42b and the first connection electrode CE1, may be disposed on the first insulating layer 3a, and disposed on the entire area of the first insulating layer 3a, but is not limited thereto.

The second insulating layer 3b may also be disposed in the area in which the intersection trench TRO is formed and may fill a portion of the area in which the intersection trench TRO is formed, in which a part of the second insulating layer 3b is removed.

Specifically, the second conductive layer 3b may be disposed on the entire area of the first insulating layer 3a on the first insulating layer 3a. A patterned second photoresist (not illustrated) may be disposed on the second insulating layer 3b, and the second insulating layer 3b exposed by the second photoresist (not illustrated) may be removed so that a part of the intersection trench TRO and the filling member 10 may be patterned. The second photoresist (not illustrated) may be removed by an ashing process.

The second insulating layer 3b disposed in the area in which the intersection trench TRO is formed may be patterned to form the filling member 10. In addition, a part of the intersection trench TRO may be defined by the first insulating layer 3a and the second insulating layer 3b. The filling member 10 may be disposed in the intersection trench TRO area.

In this case, the filling member 10 may be formed by the same process (mask) as the second insulating layer 3b and may include the same material as the second insulating layer 3b. The filling member 10 may have the same thickness as the second insulating layer 3b and have a different thickness from the third insulating layer 3c, but is not limited thereto.

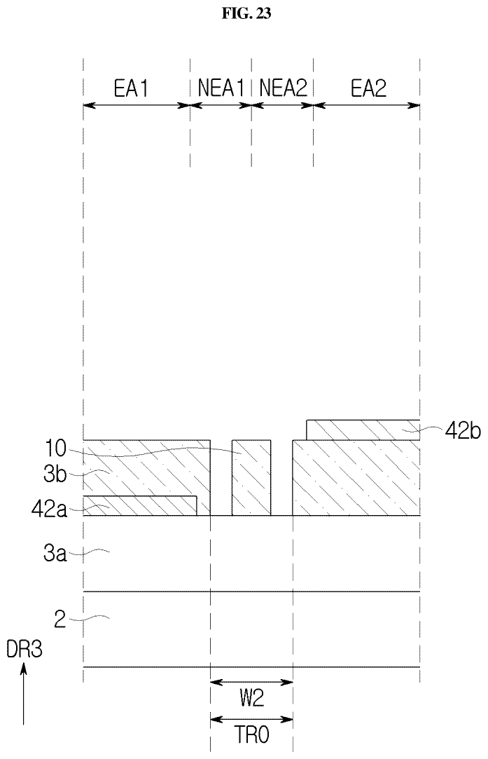

Subsequently, referring further to FIG. 23, the second reflective electrode 42b and the second connection electrode CE2 may be patterned and disposed on the second insulating layer 3b.

Specifically, a second conductive layer (not illustrated) may be disposed on the entire area of the second insulating layer 3b on the second insulating layer 3b. A patterned third photoresist (not illustrated) may be disposed on the second conductive layer (not illustrated), and the second conductive layer (not illustrated) exposed by the third photoresist (not illustrated) may be removed so that the second reflective electrode 42b and the second connection electrode CE2 may be patterned. The third photoresist (not illustrated) may be removed by an ashing process.

Although not illustrated in FIG. 23, the second connection electrode CE2 may be formed through the same process (or mask) as the second reflective electrode 42b and may include the same material. The second reflective electrode 42b may be disposed in the second sub-pixel 22, and the second connection electrode CE2 may be disposed in each of the first sub-pixel 21 and the third sub-pixel 23.

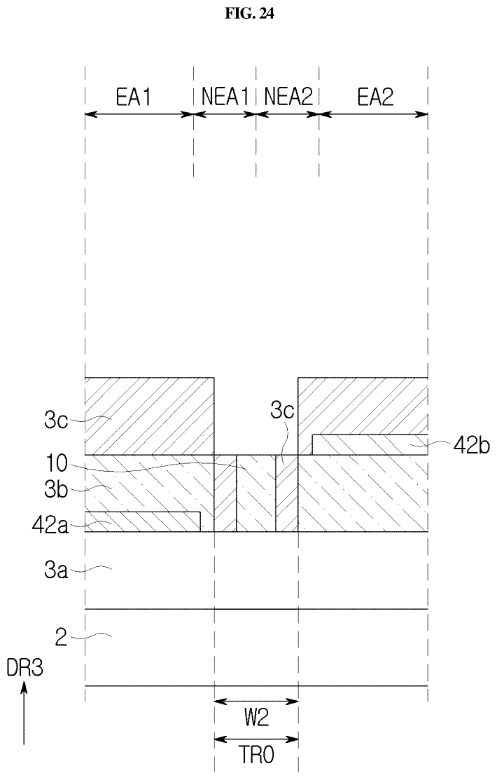

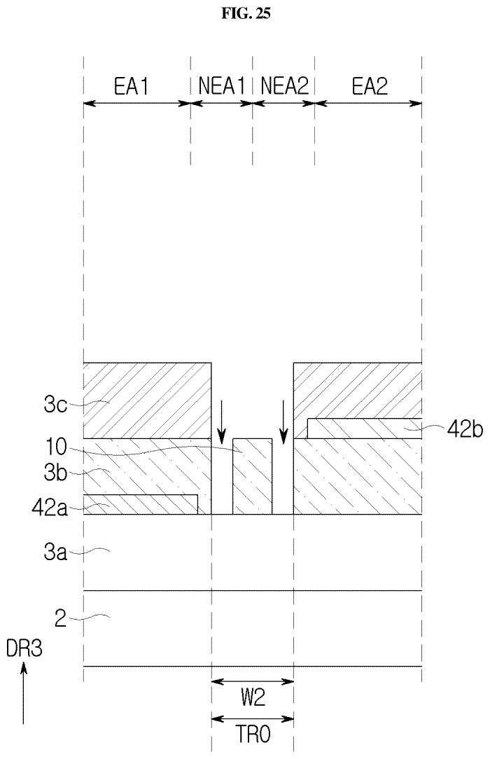

Subsequently, referring further to FIGS. 24 and 25, the third insulating layer 3c may be disposed on the second reflective electrode 42b and the second connection electrode CE2. The third insulating layer 3c may cover the second reflective electrode 42b and the second connection electrode CE2, may be disposed on the second insulating layer 3b, and disposed on the entire area of the first insulating layer 3a, but is not limited thereto.

The third insulating layer 3c may also be disposed in the area in which the intersection trench TRO is formed and may fill a portion of the area in which the intersection trench TRO is formed, from which a part of the second insulating layer 3b is removed. For example, the third insulating layer 3c may fill the area in which the second insulation layer 3b is removed around the filling member 10.

The third insulating layer 3c disposed in the area in which the intersection trench TRO is formed may be etched and patterned by a separate fourth photoresist (not illustrated), and removed from the area in which the second insulating layer 3b is removed around the filling member 10 to expose the first insulating layer 3a.

Accordingly, the intersection trench TRO may be defined by the first insulating layer 3a, the second insulating layer 3b, and the third insulating layer 3c. The filling member 10 may be disposed in the intersection trench TRO area.

During the process of forming the intersection trench TRO or the trench TR, the filling member 10 may be formed through the same mask, and thus an additional mask process may not be needed. Accordingly, even when the filling member 10 is disposed in the intersection trench TRO, it is possible to suppress or prevent an increase in the number of processes and cost.

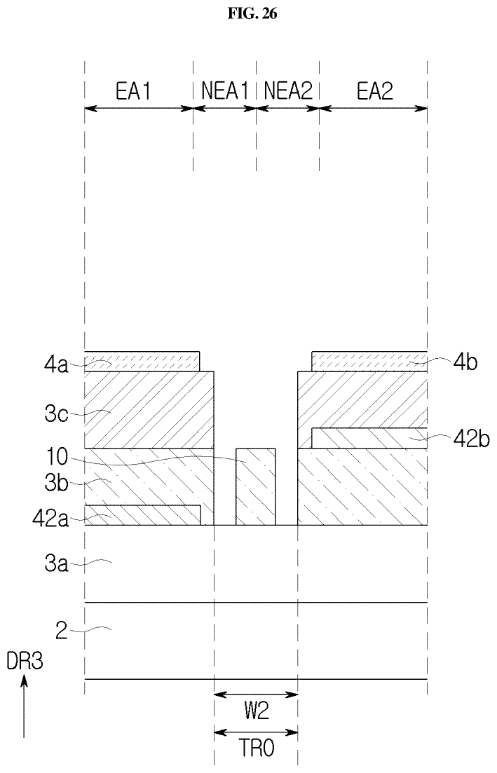

Subsequently, referring further to FIG. 26, the anode electrode layer 4 (4a, 4b, and 4c) may be disposed on the third insulating layer 3c. The anode electrode layer 4 (4a, 4b, and 4c) may be patterned and disposed in the sub-pixel 21, 22, and 23, respectively.

Specifically, a third conductive layer (not illustrated) may be disposed on the entire area of the third insulating layer 3c on the third insulating layer 3c. A patterned fifth photoresist (not illustrated) may be disposed on the third conductive layer (not illustrated), and the third conductive layer (not illustrated) exposed by the fifth photoresist (not illustrated) may be removed so that the anode electrode layer 4 (4a, 4b, and 4c) may be patterned. The fifth photoresist (not illustrated) may be removed by an ashing process.

Although not illustrated, before the anode electrode layer 4 (4a, 4b, and 4c) is disposed, the third reflective electrode 42c and the third connection electrode CE3 may be patterned and disposed on the third insulating layer 3c. The third reflective electrode 42c and the third connection electrode CE3 may be patterned on the third insulating layer 3c through a process similar to that of the first reflective electrode 42a and the first connection electrode CE1, or the second reflective electrode 42b and the second connection electrode CE2.

The anode electrode layers 4a, 4b, and 4c may be disposed on the third insulating layer 3c while covering the third reflective electrode 42c and the third connection electrode CE3.

For example, in the first sub-pixel 21, the first anode electrode 4a may be disposed on the third connection electrode CE3 in a part of the first non-light-emitting area NEA1 and disposed on the third insulating layer 3c in the first light-emitting area EA1. In the second sub-pixel 22, the second anode electrode 4b may be disposed on the third connection electrode CE3 in a part of the second non-light-emitting area NEA2 and disposed on the third insulating layer 3c in the second light-emitting area EA2. In the third sub-pixel 23, the third anode electrode 4c may be disposed on the third reflective electrode 42c across the third non-light-emitting area NEA3 and the third light-emitting area EA3. However, the embodiments of the present specification are not limited thereto.

The third anode electrode 4c of the third sub-pixel 23 may be disposed at the same height as the first anode electrode 4a of the first sub-pixel 21 and the second anode electrode 4b of the second sub-pixel 22.

Since some upper area of the third insulating layer 3c disposed in the third sub-pixel 23 area may be etched during the patterning process, the third insulating layer 3c may have a reduced thickness. For example, the third insulating layer 3c disposed in the third sub-pixel 23 area may be thinner than the third insulating layer 3c disposed in the first sub-pixel 21 area and the third insulating layer 3c disposed in the second sub-pixel 22 area. For another example, the upper surface of the third insulating layer 3c disposed in the third sub-pixel 23 area may have a lower height than the upper surface of the third insulating layer 3c disposed in the first sub-pixel 21 area and the upper surface of the third insulating layer 3c disposed in the second sub-pixel 22 area.

When some of the third insulating layers 3c disposed in the sub-pixels 21, 22, and 23 have different thicknesses, a half-tone mask may be used during the process of patterning the third insulating layer 3c, but the embodiments of the present specification are not limited thereto.

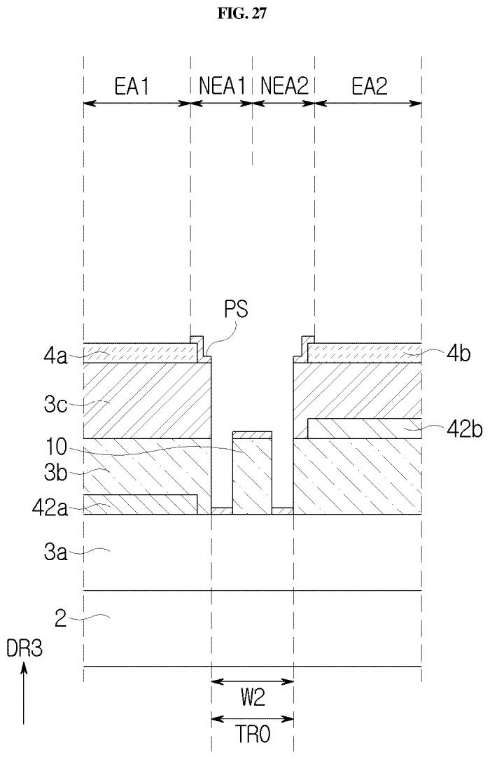

Subsequently, referring further to FIG. 27, the protective layer PS defining the light-emitting areas EA1, EA2, and EA3 may be disposed on the anode electrode layer 4 (4a, 4b, and 4c).

Although not illustrated, the protective layer PS may be disposed on the entire area of the first insulating layer 3a while covering the anode electrode layer 4 (4a, 4b, and 4c). The sixth photoresist (not illustrated) patterned to expose a part of the protective layer PS may be disposed on the protective layer PS disposed on the entire area of the first insulating layer 3a. The protective layer PS exposed by the sixth photoresist (not illustrated) may be etched and removed, and the protective layer PS may be patterned. The sixth photoresist may be removed by an ashing process.

The patterned protective layer PS may expose a part of the anode electrode layer 4 (4a, 4b, or 4c) of each sub-pixel 21, 22, or 23 to define the light-emitting area EA1, EA2, or EA3. A part of the protective layer PS may be disposed in the intersection trench TRO and disposed on the first insulating layer 3a and the filling member 10.

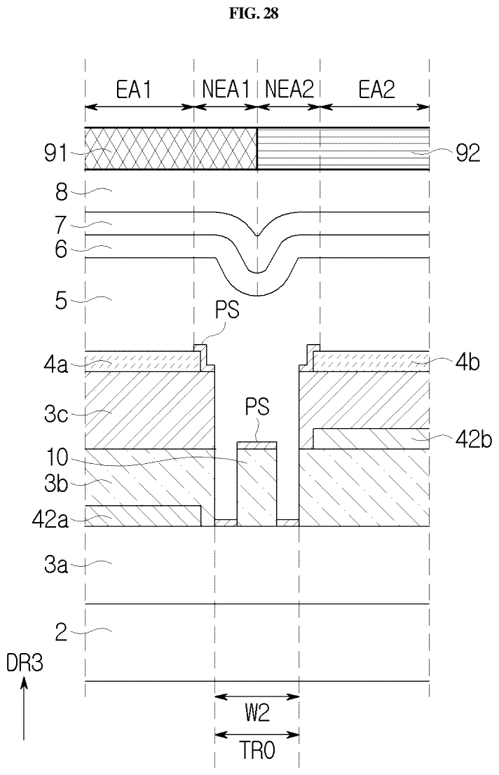

Subsequently, referring further to FIG. 28, the common light-emitting layer 5, the cathode electrode 6, the capping layer 7, the encapsulation layer 8, and the color filter layer 9 may be sequentially stacked on the anode electrode layer 4 (4a, 4b, and 4c) and the protective layer PS.

The common light-emitting layer 5, the cathode electrode 6, the capping layer 7, the encapsulation layer 8, and the color filter layer 9 may be integrally disposed on the entire area of the substrate 2 without distinction between the sub-pixels 21, 22, and 23.

Since the filling member 10 is disposed in each intersection trench TRO, even when the intersection trench TRO has the second width W2 greater than the first width W1, the filling member 10 may fill a part of the intersection trench TRO. Accordingly, the first stack EL1 (see FIG. 6) and the first charge generation layer CGL1 (see FIG. 6) are separated in each sub-pixel 21, 22, or 23, and the entire area of the first charge generation layer CGL1 (see FIG. 6) may be covered by the second stack EL2 (see FIG. 6). That is, the second stack EL2 (see FIG. 6) may be disposed between the first charge generation layer CGL1 (see FIG. 6) and the cathode electrode 6.

It is possible to prevent or at least reduce a leakage current between the adjacent sub-pixels 21, 22, and 23, prevent or at least reduce a short circuit between the charge generation layer CGL1 and the cathode electrode 6, and prevent or at least reduce light color mixing.

Hereinafter, other embodiments of the present specification will be described. For contents substantially the same as those described with reference to FIGS. 1 to 9 among components included in other embodiments, the same reference numerals are given, and overlapping contents may be omitted or briefly described.

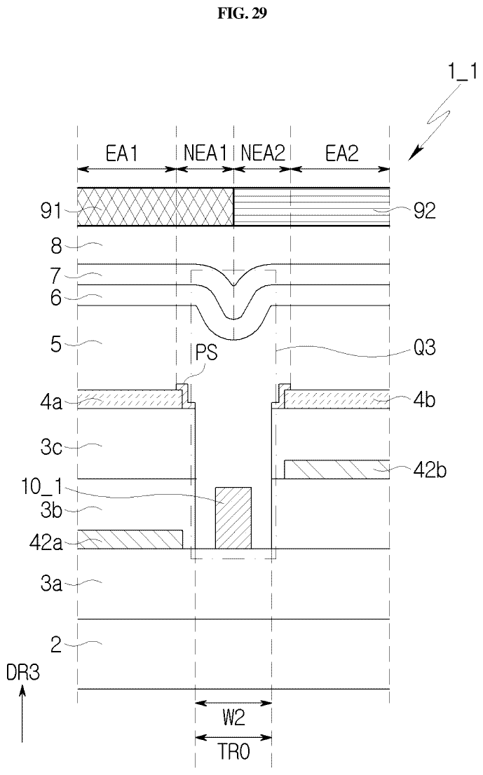

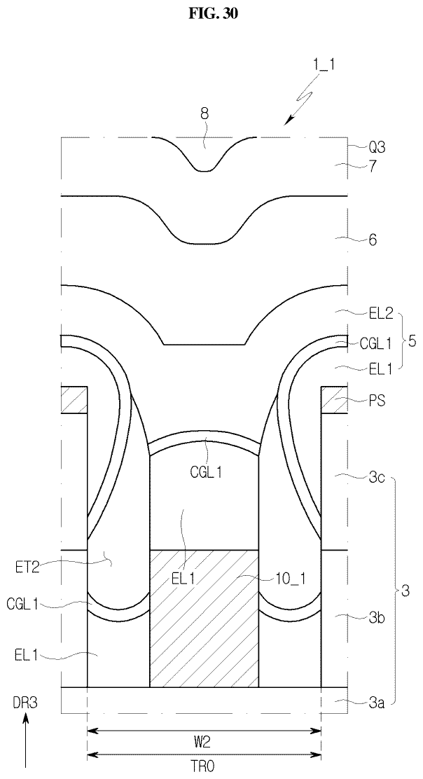

FIG. 29 is a cross-sectional view of an intersection trench area of the display apparatus according to another embodiment. FIG. 30 is an enlarged view of area Q3 in FIG. 29 according to one embodiment.

Referring to FIGS. 29 and 30, a filling member 10_1 of a display apparatus 1_1 according to the present embodiment may include the same material as the protective layer PS and may be formed by the same process.

The filling member 10_1 may be disposed in the intersection trench TRO and spaced apart from the side surfaces of the second insulating layer 3b and the side surfaces of the third insulating layer 3c defining the intersection trench TRO.

The filling member 10_1 may include the same material as the protective layer PS and may be formed along with the protective layer PS through the same process (or mask). A thickness (a thickness in the third direction DR3) of the filling member 10_1 may be smaller than a thickness (a thickness in the third direction DR3) of the second insulating layer 3b and a thickness (a thickness in the third direction DR3) of the third insulating layer 3c, but is not limited thereto.

Even in this case, since the filling member 10_1 may be disposed in the intersection trench TRO to fill a part of the intersection trench TRO, it is possible to prevent the second stack EL2 and the cathode electrode 6 from penetrating the intersection trench TRO, thereby preventing a short circuit defect in which the cathode electrode 6 comes into contact with the first charge generation layer CGL1.

As a result, by arranging the filling member 10 in each intersection trench TRO, even when the intersection trench TRO is over-etched and formed to have a broad width (the second width W2), the first charge generation layer CGL1 may be separated in each sub-pixel 21, 22, or 23 and can prevent a short circuit defect between the cathode electrode 6 and the first charge generation layer CGL1. Accordingly, it is possible to suppress or prevent a leakage current between the sub-pixels 21, 22, and 23 and suppress or prevent light color mixing.

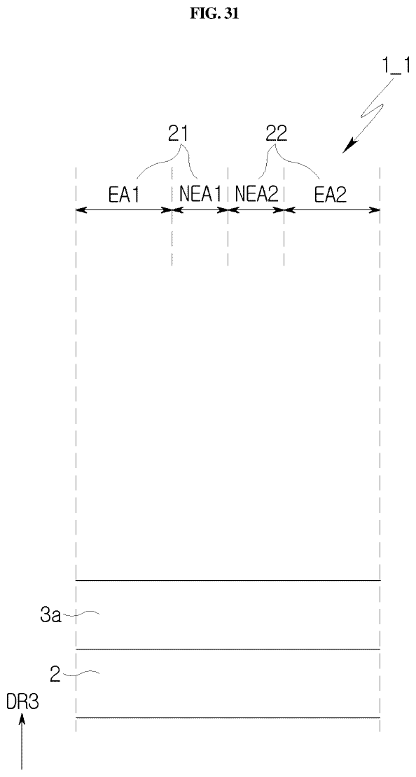

FIGS. 31 to 39 are cross-sectional views for each process in a method of manufacturing a display apparatus according to the embodiment of FIGS. 29 and 30.

Hereinafter, the method of manufacturing the display apparatus 1_1 will be described through a cross section around the intersection trench TRO between the first sub-pixel 21 and the second sub-pixel 22, but the corresponding description is not limited thereto and may be applied to all intersection trenches TROs and filling members 10_1 in the same manner.

Referring to FIGS. 1 to 4, 29, 30, and 31, the substrate 2 capable of supporting other components disposed thereon is provided. The first insulating layer 3a may be disposed on the substrate 2. Circuit elements including the plurality of thin film transistors 31, 32, and 33, various signal lines, capacitors, etc. may be provided in the first insulating layer 3a of each sub-pixel 21, 22, or 23.

The first insulating layer 3a may be disposed on the entire area of the substrate 2, but is not limited thereto.

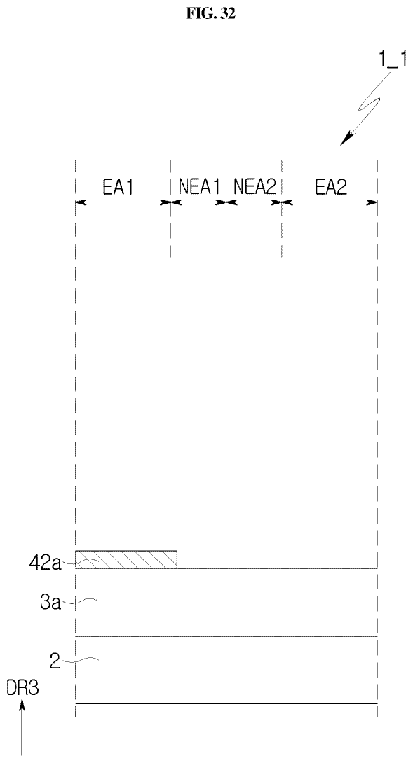

Subsequently, referring further to FIG. 32, the first reflective electrode 42a and the first connection electrode CE1 may be patterned and disposed on the first insulating layer 3a.

Specifically, a first conductive layer (not illustrated) may be disposed on the entire area of the first insulating layer 3a. A patterned first photoresist (not illustrated) may be disposed on the first conductive layer (not illustrated), and the first conductive layer (not illustrated) exposed by the first photoresist (not illustrated) may be removed so that the first reflective electrode 42a and the first connection electrode CE1 may be patterned. The first photoresist (not illustrated) may be removed by an ashing process.

Although not illustrated in FIG. 32, the first connection electrode CE1 may be formed through the same process (or mask) as the first reflective electrode 42a and may include the same material. The first reflective electrode 42a may be disposed in the first sub-pixel 21, and the first connection electrode CE1 may be disposed in each of the second sub-pixel 22 and the third sub-pixel 23.

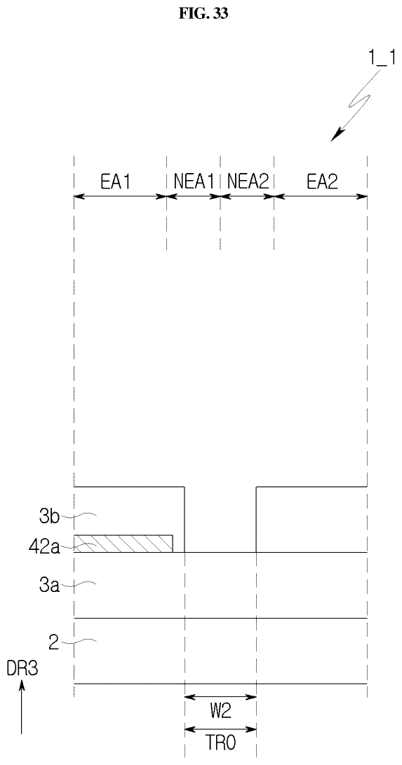

Subsequently, referring further to FIG. 33, the second insulating layer 3b may be disposed on the first reflective electrode 42a and the first connection electrode CE1. The second insulating layer 3b may cover the first reflective electrode 42a and the first connection electrode CE1 and may be disposed on the entire area of the first insulating layer 3a.

A patterned second photoresist (not illustrated) may be disposed on the second insulating layer 3b disposed on the entire area of the first insulating layer 3a, and the second insulating layer 3b in the area exposed by the second photoresist (not illustrated) may be removed to pattern the second insulating layer 3b. The second photoresist (not illustrated) may be removed by an ashing process.

A part of the second insulating layer 3b disposed across the entire area of the first insulating layer 3a may be removed from the area in which the intersection trench TRO is formed to expose the first insulating layer 3a. However, the embodiments of the present specification are not limited thereto, and only some area of the second insulating layer 3b may be recessed in the third direction DR3 without exposing the first insulating layer 3a.

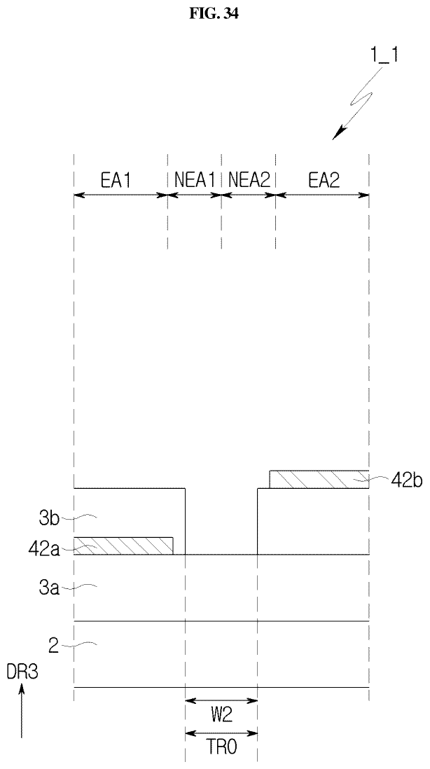

Subsequently, referring further to FIG. 34, the second reflective electrode 42b and the second connection electrode CE2 may be patterned and disposed on the second insulating layer 3b.

Specifically, a second conductive layer (not illustrated) may be disposed on the entire area of the second insulating layer 3b on the second insulating layer 3b. A patterned third photoresist (not illustrated) may be disposed on the second conductive layer (not illustrated), and the second conductive layer (not illustrated) exposed by the third photoresist (not illustrated) may be removed so that the second reflective electrode 42b and the second connection electrode CE2 may be patterned. The third photoresist (not illustrated) may be removed by an ashing process.

Although not illustrated in FIG. 34, the second connection electrode CE2 may be formed through the same process (or mask) as the second reflective electrode 42b and may include the same material. The second reflective electrode 42b may be disposed in the second sub-pixel 22, and the second connection electrode CE2 may be disposed in each of the first sub-pixel 21 and the third sub-pixel 23.

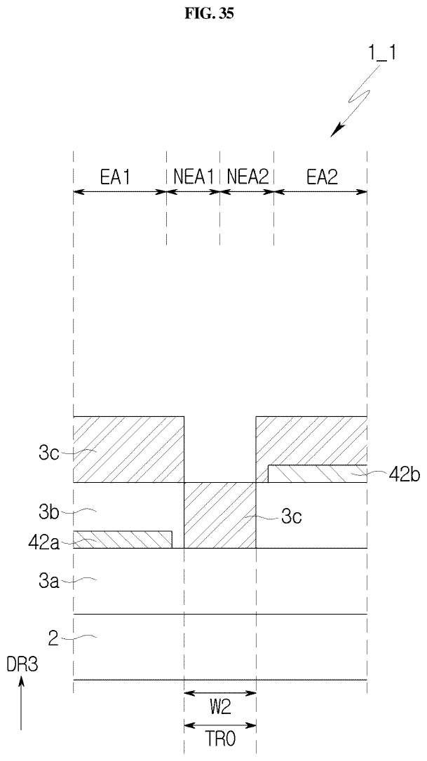

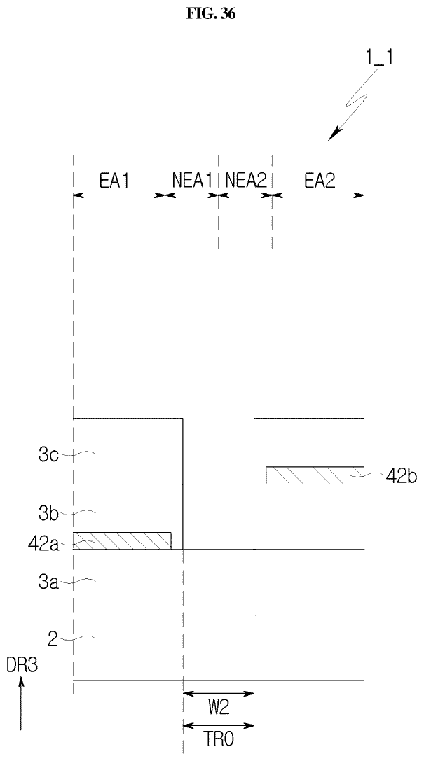

Subsequently, referring further to FIGS. 35 and 36, the third insulating layer 3c may be disposed on the second reflective electrode 42b and the second connection electrode CE2. The third insulating layer 3c may cover the second reflective electrode 42b and the second connection electrode CE2, may be disposed on the second insulating layer 3b, and disposed on the entire area of the first insulating layer 3a, but is not limited thereto.

The third insulating layer 3c may also be disposed in the area in which the intersection trench TRO is formed and may fill a portion of the area in which the intersection trench TRO is formed, in which a part of the second insulating layer 3b is removed.

The third insulating layer 3c disposed in the area in which the intersection trench TRO is formed may be removed after etched and patterned by a separate fourth photoresist (not illustrated). Accordingly, the intersection trench TRO may be defined by the first insulating layer 3a, the second insulating layer 3b, and the third insulating layer 3c.

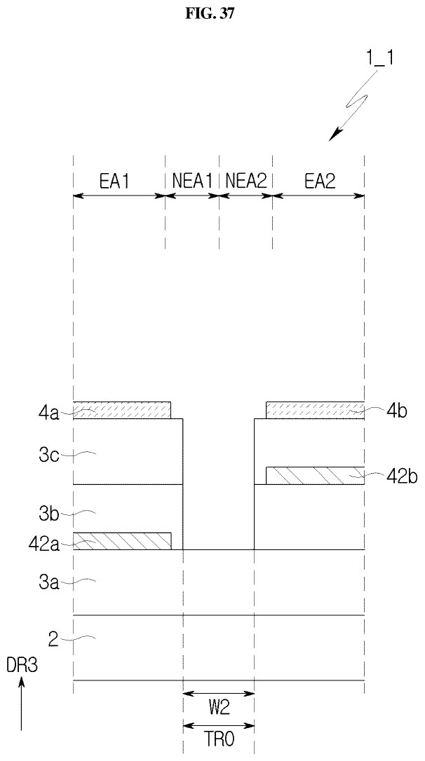

Subsequently, referring further to FIG. 37, the anode electrode layer 4 (4a, 4b, and 4c) may be disposed on the third insulating layer 3c. The anode electrode layer 4 (4a, 4b, and 4c) may be patterned and disposed in the sub-pixels 21, 22, and 23, respectively.

Specifically, a third conductive layer (not illustrated) may be disposed on the entire area of the third insulating layer 3c on the third insulating layer 3c. A patterned fifth photoresist (not illustrated) may be disposed on the third conductive layer (not illustrated), and the third conductive layer (not illustrated) exposed by the fifth photoresist (not illustrated) may be removed so that the anode electrode layer 4 (4a, 4b, and 4c) may be patterned. The fifth photoresist (not illustrated) may be removed by an ashing process.

Although not illustrated, before the anode electrode layer 4 (4a, 4b, and 4c) is disposed, the third reflective electrode 42c and the third connection electrode CE3 may be patterned and disposed on the third insulating layer 3c. The third reflective electrode 42c and the third connection electrode CE3 may be patterned on the third insulating layer 3c through a process similar to that of the first reflective electrode 42a and the first connection electrode CE1, or the second reflective electrode 42b and the second connection electrode CE2.

The anode electrode layers 4a, 4b, and 4c may be disposed on the third insulating layer 3c while covering the third reflective electrode 42c and the third connection electrode CE3.

For example, in the first sub-pixel 21, the first anode electrode 4a may be disposed on the third connection electrode CE3 in a part of the first non-light-emitting area NEA1 and disposed on the third insulating layer 3c in the first light-emitting area EA1. In the second sub-pixel 22, the second anode electrode 4b may be disposed on the third connection electrode CE3 in a part of the second non-light-emitting area NEA2 and disposed on the third insulating layer 3c in the second light-emitting area EA2. In the third sub-pixel 23, the third anode electrode 4c may be disposed on the third reflective electrode 42c across the third non-light-emitting area NEA3 and the third light-emitting area EA3. However, the embodiments of the present specification are not limited thereto.

The third anode electrode 4c of the third sub-pixel 23 may be disposed at the same height as the first anode electrode 4a of the first sub-pixel 21 and the second anode electrode 4b of the second sub-pixel 22.

Although not illustrated, since some upper area of the third insulating layer 3c disposed in the third sub-pixel 23 area may be etched during the patterning process, the third insulating layer 3c may have a reduced thickness. For example, the third insulating layer 3c disposed in the third sub-pixel 23 area may be thinner than the third insulating layer 3c disposed in the first sub-pixel 21 area and the third insulating layer 3c disposed in the second sub-pixel 22 area. For another example, an upper surface of the third insulating layer 3c disposed in the third sub-pixel 23 area may have a lower height than an upper surface of the third insulating layer 3c disposed in the first sub-pixel 21 area and an upper surface of the third insulating layer 3c disposed in the second sub-pixel 22 area.

When some of the third insulating layers 3c disposed in the sub-pixels 21, 22, and 23 have different thicknesses, a half-tone mask may be used during the process of patterning the third insulating layer 3c, but the embodiments of the present specification are not limited thereto.

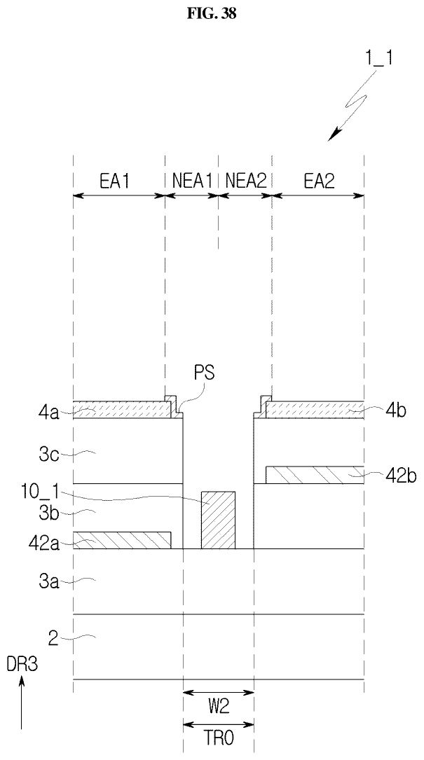

Subsequently, referring further to FIG. 38, the protective layer PS defining the light-emitting areas EA1, EA2, and EA3 may be disposed on the anode electrode layer 4 (4a, 4b, and 4c), and a filling member 10_1 may be formed by the same process.

Although not illustrated, the protective layer PS may be disposed on the entire area of the first insulating layer 3a while covering the anode electrode layer 4 (4a, 4b, and 4c). A sixth photoresist (not illustrated) patterned to expose a part of the protective layer PS may be disposed on the protective layer PS disposed on the entire area of the first insulating layer 3a.

The protective layer PS exposed by the sixth photoresist (not illustrated) may be etched and removed, and the protective layer PS may be patterned. During the process of patterning the protective layer PS, a part of the protective layer PS disposed inside the intersection trench TRO area may be removed to form the filling member 10_1. The sixth photoresist may be removed by an ashing process.

The patterned protective layer PS may expose a part of the anode electrode layer 4 (4a, 4b, or 4c) of each sub-pixel 21, 22, or 23 to define the light-emitting area EA1, EA2, or EA3. A part of the protective layer PS may be disposed in the intersection trench TRO and disposed on the first insulating layer 3a and the filling member 10_1.

In this case, the filling member 10_1 may be formed by the same process (mask) as the protective layer PS and may include the same material as the protective layer PS. The filling member 10_1 may have a different thickness from the third insulating layer 3c and the second insulating layer 3b and have a smaller thickness than the third insulating layer 3c and the second insulating layer 3b, but is not limited thereto.

During the process of forming the intersection trench TRO or the trench TR, the filling member 10_1 may be formed through the same mask, and thus an additional mask process may not be needed. Accordingly, even when the filling member 10_1 is disposed in the intersection trench TRO, it is possible to suppress or prevent an increase in the number of processes and cost.

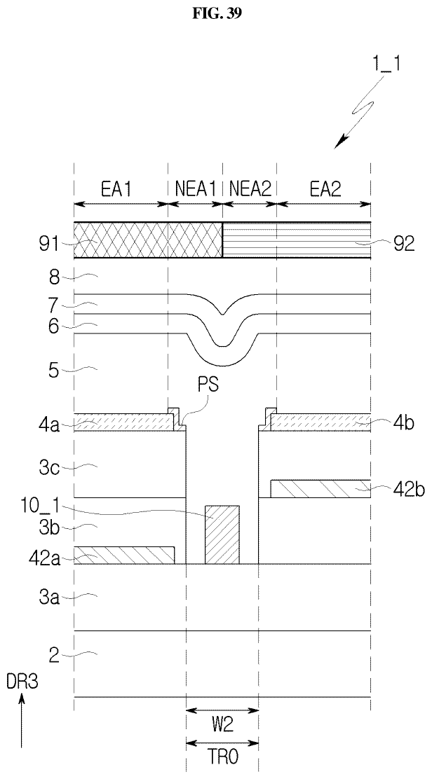

Referring further to FIG. 39, the common light-emitting layer 5, the cathode electrode 6, the capping layer 7, the encapsulation layer 8, and the color filter layer 9 may be sequentially stacked on the anode electrode layer 4 (4a, 4b, and 4c) and the protective layer PS.

The common light-emitting layer 5, the cathode electrode 6, the capping layer 7, the encapsulation layer 8, and the color filter layer 9 may be integrally disposed on the entire area of the substrate 2 without distinction between the sub-pixels 21, 22, and 23.

Since the filling member 10_1 is disposed in each intersection trench TRO, even when the intersection trench TRO has the second width W2 greater than the first width W1, the filling member 10_1 may fill a part of the intersection trench TRO. Accordingly, the first stack EL1 and the first charge generation layer CGL1 may be separated in each sub-pixel 21, 22, or 23, and the entire area of the first charge generation layer CGL1 may be covered by the second stack EL2. That is, the second stack EL2 may be disposed between the first charge generation layer CGL1 and the cathode electrode 6.

It is possible to prevent or at least reduce a leakage current between the adjacent sub-pixels 21, 22, and 23, prevent a short circuit between the charge generation layer CGL1 and the cathode electrode 6, and prevent light color mixing.

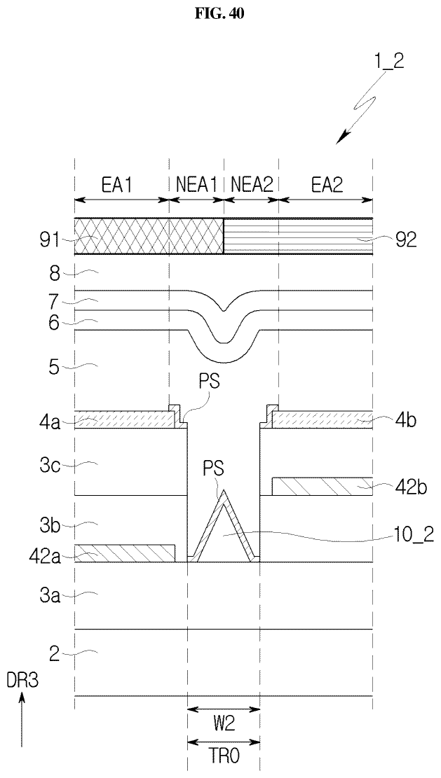

FIG. 40 is a cross-sectional view of a display apparatus according to still another embodiment.

FIG. 40 illustrates a cross section around an intersection trench TRO of a display apparatus 1_2 according to still another embodiment.

Referring to FIG. 40, the display apparatus 1_2 according to the present embodiment may include a filling member 10_2 in the intersection trench TRO area, and the filling member 10_2 may be formed in a triangular shape based on the cross-section view.

The filling member 10_2 may be formed by the same process as the second insulating layer 3b or the third insulating layer 3c and may include the same material as the second insulating layer 3b or the third insulating layer 3c. However, the filling member 10_2 is not limited thereto, may be formed by the same process as the protective layer PS, and may include the same material as the protective layer PS.

A part of the protective layer PS may be disposed on the filling member 10_2, but is not limited thereto, and the protective layer PS may not be disposed in the intersection trench TRO.

Even in this case, as the filling member 10_2 is disposed in each intersection trench TRO, even when the intersection trench TRO has the second width W2 greater than the first width W1, the filling member 10_2 fills a part of the intersection trench TRO, and thus the first stack EL1 (see FIG. 6) and the first charge generation layer CGL1 (see FIG. 6) may be separated in each sub-pixel 21, 22, or 23, and the second stack EL2 (see FIG. 6) may be disposed between the first charge generation layer CGL1 (see FIG. 6) and the cathode electrode 6.

It is possible to prevent or at least reduce a leakage current between sub-pixels 21, 22, and 23, prevent a short circuit between the charge generation layer CGL1 and the cathode electrode 6, and prevent light color mixing.

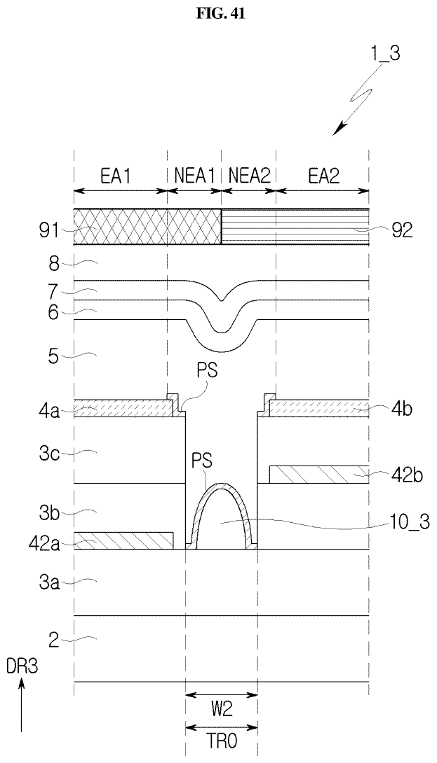

FIG. 41 is a cross-sectional view of a display apparatus according to yet another embodiment.

FIG. 41 illustrates a cross section around an intersection trench TRO of a display apparatus 1_3 according to yet another embodiment.

Referring to FIG. 41, the display apparatus 1_3 according to the present embodiment may include a filling member 10_3 in the intersection trench TRO area, and the filling member 10_3 may be formed in a circular shape based on the cross-sectional view.

The filling member 10_3 may be formed by the same process as the second insulating layer 3b or the third insulating layer 3c and may include the same material as the second insulating layer 3b or the third insulating layer 3c.

However, the filling member 10_3 is not limited thereto, may be formed by the same process as the protective layer PS, and may include the same material as the protective layer PS.

A part of the protective layer PS may be disposed on the filling member 10_3, but is not limited thereto, and the protective layer PS may not be disposed in the intersection trench TRO.

Even in this case, as the filling member 10_3 is disposed in each intersection trench TRO, even when the intersection trench TRO has the second width W2 greater than the first width W1, the filling member 10_3 fills a part of the intersection trench TRO, and thus the first stack EL1 (see FIG. 6) and the first charge generation layer CGL1 (see FIG. 6) may be separated in each sub-pixel 21, 22, or 23, and the second stack EL2 (see FIG. 6) may be disposed between the first charge generation layer CGL1 (see FIG. 6) and the cathode electrode 6.

It is possible to prevent or at least reduce a leakage current between sub-pixels 21, 22, and 23, prevent a short circuit between the charge generation layer CGL1 and the cathode electrode 6, and prevent light color mixing.

A display apparatus according to various embodiments of the present specification may be described as follows.

According to embodiments of the present specification, there is provided a display apparatus including a substrate including sub-pixels, an insulating layer disposed on the substrate and having a trench formed between the adjacent sub-pixels, and a filling member disposed in the trench, in which the trench includes a first trench extending in a first direction and disposed between the adjacent sub-pixels in a second direction intersecting the first direction, a second trench extending in the second direction and disposed between the adjacent sub-pixels in the first direction, and an intersection trench located in an intersection area between the first trench and the second trench, and the filling member is located in the intersection trench.

According to various embodiments of the present specification, the trench may be formed to be recessed from an upper surface of an insulating layer.

According to various embodiments of the present specification, a width of the intersection trench may be greater than a width of the first trench and a width of the second trench. According to various embodiments of the present specification, the sub-pixels may include a first sub-pixel, a second sub-pixel, and a third sub-pixel, the first sub-pixel may include a first reflective electrode, the second sub-pixel may include a second reflective electrode, the third sub-pixel may include a third reflective electrode, and the first reflective electrode, the second reflective electrode, and the third reflective electrode may be located on different layers.

According to various embodiments of the present specification, the insulating layer may include a first insulating layer between the substrate and the first reflective electrode, a second insulating layer between the first reflective electrode and the second reflective electrode, and a third insulating layer between the second reflective electrode and the third reflective electrode, and the trench may recess the third insulating layer and the second insulating layer.

According to various embodiments of the present specification, the display apparatus may further include an anode electrode layer on the third insulating layer, in which the anode electrode layer may include a first anode electrode of the first sub-pixel, a second anode electrode of the second sub-pixel, and a third anode electrode directly disposed on the third reflective electrode of the third sub-pixel.

According to various embodiments of the present specification, the first sub-pixel may include a first light-emitting area and a first non-light-emitting area around the first light-emitting area, the second sub-pixel may include a second light-emitting area and a second non-light-emitting area around the second light-emitting area, the third sub-pixel may include a third light-emitting area and a third non-light-emitting area around the third light-emitting area, each of the first to third sub-pixels may further include a bank disposed on the anode electrode layer, and the bank may be disposed on the first non-light-emitting area, the second non-light-emitting area, and the third non-light-emitting area.

According to various embodiments of the present specification, the filling member may be spaced apart from the insulating layer on the adjacent sub-pixels.

According to various embodiments of the present specification, the bank may be further disposed on the filling member and may overlap the filling member.

According to various embodiments of the present specification, the bank may be further disposed between the filling member and the insulating layer, and the bank between the filling member and the insulating layer may come into direct contact with the first insulating layer.

According to various embodiments of the present specification, the filling member may include the same material as the bank.

According to various embodiments of the present specification, the display apparatus may further include a common light-emitting layer on the anode electrode layer and the bank, in which the common light-emitting layer may be disposed across adjacent sub-pixels and may overlap the filling member.

According to various embodiments of the present specification, the common light-emitting layer may include a first stack, a charge generation layer on the first stack, and a second stack on the charge generation layer, and the first stack and the charge generation layer may be separated by the trench.

According to various embodiments of the present specification, the second stack may be continuous on the trench.

According to various embodiments of the present specification, the filling member may include the same material as the third insulating layer.

According to various embodiments of the present specification, the filling member may have a different thickness from the second insulating layer.

According to various embodiments of the present specification, the filling member may include the same material as the second insulating layer.

According to embodiments of the present specification, there is provided a display apparatus including a substrate including sub-pixels, an insulating layer disposed on the substrate and having a trench formed between the adjacent sub-pixels, and a filling member disposed in the trench, in which the filling member is spaced apart from the insulating layer, and a thickness of the filling member is smaller than a thickness of the insulating layer.

According to various embodiments of the present specification, the trench may include a first trench extending in a first direction, a second trench extending in a second direction intersecting the first direction, and an intersection trench in which the first trench intersects the second trench, and the filling member may be disposed in the intersection trench.

According to various embodiments of the present specification, and the first trench and the second trench may be disposed between the sub-pixels.

Although the embodiments have been described above with reference to the accompanying drawings, those skilled in the art to which the present specification pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### Description of Reference Numerals

1: display apparatus
2: substrate
3: insulating layer
4: anode electrode layer
5: common light-emitting layer
6: cathode electrode
7: capping layer
8: encapsulation layer
9: color filter layer
42: reflective layer
CE: connection electrode
TR: trench
TRH: first trench
TRV: second trench
TRO: intersection trench
10: filling member

What is claimed is:

1. A display apparatus comprising:
a substrate including sub-pixels;
an insulating layer on the substrate, the insulating layer having a trench located between adjacent sub-pixels from the sub-pixels; and
a filling member in the trench,
wherein the trench includes:
a first trench extending in a first direction, the first trench disposed between the adjacent sub-pixels in a second direction intersecting the first direction;
a second trench extending in the second direction, the second trench disposed between the adjacent sub-pixels in the first direction; and
an intersection trench located in an intersection area of the first trench and the second trench, the filling member located in the intersection trench.

2. The display apparatus of claim 1, wherein the trench is recessed from an upper surface of the insulating layer.

3. The display apparatus of claim 2, wherein a width of the intersection trench is greater than a width of the first trench and a width of the second trench.

4. The display apparatus of claim 3, wherein the sub-pixels include a first sub-pixel, a second sub-pixel, and a third sub-pixel,
the first sub-pixel includes a first reflective electrode, the second sub-pixel includes a second reflective electrode, the third sub-pixel includes a third reflective electrode, and
the first reflective electrode, the second reflective electrode, and the third reflective electrode are located on different layers.

5. The display apparatus of claim 4, wherein the insulating layer includes a first insulating layer between the substrate and the first reflective electrode, a second insulating layer between the first reflective electrode and the second reflective electrode, and a third insulating layer between the second reflective electrode and the third reflective electrode,
and the trench recesses the third insulating layer and the second insulating layer.

6. The display apparatus of claim 5, further comprising:
an anode electrode layer on the third insulating layer,
wherein the anode electrode layer includes a first anode electrode of the first sub-pixel, a second anode electrode of the second sub-pixel, and a third anode electrode directly on the third reflective electrode of the third sub-pixel.

7. The display apparatus of claim 6, wherein the first sub-pixel includes a first light-emitting area and a first non-light-emitting area around the first light-emitting area, the second sub-pixel includes a second light-emitting area and a second non-light-emitting area around the second light-emitting area, the third sub-pixel includes a third light-emitting area and a third non-light-emitting area around the third light-emitting area,
wherein each of the first sub-pixel to the third sub-pixel further includes a bank disposed on the anode electrode layer and the bank is on the first non-light-emitting area, the second non-light-emitting area, and the third non-light-emitting area.

8. The display apparatus of claim 7, wherein the filling member is spaced apart from the insulating layer on the adjacent sub-pixels.

9. The display apparatus of claim 8, wherein the bank is further disposed on the filling member and overlaps the filling member.

10. The display apparatus of claim 9, wherein the bank is further disposed between the filling member and the insulating layer, and the bank is between the filling member and the insulating layer comes into direct contact with the first insulating layer.

11. The display apparatus of claim 7, wherein the filling member includes a same material as the bank.

12. The display apparatus of claim 7, further comprising:
a common light-emitting layer on the anode electrode layer and the bank,
wherein the common light-emitting layer is disposed across the adjacent sub-pixels and overlaps the filling member.

13. The display apparatus of claim 12, wherein the common light-emitting layer includes a first stack, a charge generation layer on the first stack, and a second stack on the charge generation layer, and the first stack and the charge generation layer are separated by the trench.

14. The display apparatus of claim 13, wherein the second stack is continuous on the trench.

15. The display apparatus of claim 5, wherein the filling member includes a same material as the third insulating layer.

16. The display apparatus of claim 15, wherein a thickness of the filling member is different from a thickness of the second insulating layer.

17. The display apparatus of claim 5, wherein the filling member includes a same material as the second insulating layer.

18. A display apparatus comprising:
a substrate including sub-pixels;
an insulating layer on the substrate, the insulating layer having a trench located between adjacent sub-pixels from the sub-pixels; and
a filling member in the trench, the filling member spaced apart from the insulating layer,
wherein a thickness of the filling member is smaller than a thickness of the insulating layer.

19. The display apparatus of claim 18, wherein the trench includes a first trench extending in a first direction, a second trench extending in a second direction intersecting the first direction, and an intersection trench in which the first trench intersects the second trench, and the filling member is in the intersection trench.

20. The display apparatus of claim 19, wherein a sub-pixel from the sub-pixels includes a plurality of sub-pixels, and the first trench and the second trench are between the sub-pixels.
